(19) United States
(12) Patent Application Publication
(10) Pub. No.: US 2026/0182335 A1
(43) Pub. Date: Jun. 25, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Chue San YOO, Hsin-Chu (TW); Harry-HakLay CHUANG, Zhubei City (TW); Li-Feng TENG, Hsinchu City (TW); Wei-Cheng WU, Zhubei City (TW)

(21) Appl. No.: 18/988,106

(22) Filed: Dec. 19, 2024

(51) Int. Cl. H01L 23/522; H01L 21/768; H01L 23/00

(52) U.S. Cl. CPC H10W 20/42; H10W 20/01; H10W 80/312; H10W 80/327; H10W 90/792

(57) ABSTRACT

A device layer and an interconnect layer of a semiconductor device are formed as separate semiconductor structures (e.g., on different semiconductor substrates) and then, following formation of the device and interconnect layers, the separate semiconductor structures are bonded together. In some implementations, a charge reduction process (e.g., an ultraviolet (UV) light curing process) is performed on a first semiconductor structure including the interconnect layer so that charges resulting from plasma processing to form the interconnect layer can be removed prior to bonding the first semiconductor structure including the interconnect layer to a second semiconductor structure including the device layer. As a result of the charge removal, current flow in dielectric layers (e.g., gate oxide layers) in a device layer, and resulting plasma-induced damage to the dielectric layers, can be reduced and/or prevented in comparison to when the device layer and interconnect layer are sequentially formed on the same semiconductor substrate.

### BACKGROUND

Bonding in the semiconductor industry is a technique that may be used to form stacked semiconductor devices and three-dimensional integrated circuits. Some examples of bonding include wafer-to-wafer bonding, die-to-wafer bonding, and die-to-die bonding, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are diagrams of examples of a semiconductor device described herein.

FIGS. 2A-2K are diagrams of an example implementation of forming a semiconductor structure described herein.

FIGS. 3A-3F are diagrams of an example implementation of forming a semiconductor structure described herein.

FIG. 4 is a diagrams of an example implementation of forming a semiconductor device described herein.

FIGS. 5A-5C are diagrams of example implementations of the semiconductor device described herein.

FIGS. 6A and 6B are diagrams of example implementations of the semiconductor device described herein.

FIG. 7 is a diagram of an example implementations of the semiconductor device described herein.

FIG. 8 is a flowchart of an example process associated with forming a semiconductor device described herein.

FIG. 9 is a flowchart of an example process associated with forming a semiconductor device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

An interconnect layer is a region of a semiconductor device that includes a plurality of layers of conductive structures that are arranged to carry signals and/or to provide power distribution throughout the semiconductor device. The plurality of layers of conductive structures may include various vertically-arranged layers of interconnect structures (e.g., vias, interconnects) and layers of metallization structures (e.g., trenches, metallization layers, conductive lines, conductive traces). An interconnect layer of a semiconductor device may be formed above a device layer of the semiconductor device. The device layer may include a substrate layer of the semiconductor device and integrated circuit devices (e.g., transistors, capacitors, diodes, memory cells) in and/or on the semiconductor substrate.

The device layer and the interconnect layer may be formed sequentially in that the device layer is formed first, followed by the interconnect layer being formed above the device layer. This sequential process may involve many processing operations, and performing these processing operations sequentially on the same semiconductor substrate may increase the likelihood that the semiconductor device will experience a process-induced defect. For example, plasma processes, such as plasma etching processes, cause current to flow through thin oxide layers (e.g., gate oxide layers). As a result of the current flowing through the oxide layers, the oxide layers may become damaged and/or break down. The plasma-induced damage and/or breaking down of the oxide layers can cause increased in current leakage, decreases in device yield, and/or reduced device reliability. In some instances, the plasma-induced damage may result in a semiconductor device not satisfying acceptance testing, requiring rework and/or scrapping of a fabricated device that took multiple weeks or multiple months to be built.

In some implementations described herein, a device layer and an interconnect layer of a semiconductor device are formed as separate semiconductor structures (e.g., on different semiconductor substrates) and then, following formation of the device and interconnect layers, the separate semiconductor structures are bonded together. In some implementations, a charge reduction process (e.g., an ultraviolet (UV) light curing process) is performed on a first semiconductor structure including the interconnect layer so that charges resulting from plasma processing to form the interconnect layer can be removed prior to bonding the first semiconductor structure including the interconnect layer to a second semiconductor structure including the device layer. As a result of the charge removal, current flow in dielectric layers (e.g., gate oxide layers) in a device layer, and the resulting plasma-induced damage to the dielectric layers, can be reduced and/or prevented in comparison to when the device layer and the interconnect layer are sequentially formed on the same semiconductor substrate.

Additionally, by fabricating the device layer and the interconnect layer as different semiconductor structures to be bonded together, the device layer and the interconnect layer can be manufactured concurrently, thereby reducing the overall time for manufacturing the semiconductor device in comparison to when the device layer and the interconnect layer are sequentially formed on the same semiconductor substrate. For example, manufacturing the device layer and the interconnect layer on separate semiconductor substrates may enable processes that are used to form the device layer and the interconnect layer to be customized for the device layer and the interconnect layer, thereby increasing manufacturing efficiency and improving resulting device performance. In more detail, manufacturing techniques that may be beneficial for the interconnect layer, but detrimental to the device layer (e.g., plasma operations), may be used to manufacture the interconnect layer on a separate semiconductor substrate, with little or no impact on the device layer. Similarly, manufacturing techniques that may be beneficial for the device layer, but detrimental to the interconnect layer, may be used to manufacture the device layer on a separate semiconductor substrate, with little or no impact to the interconnect layer.

Additionally and/or alternatively, in some implementations, the techniques described herein for separately manufacturing a device layer and an interconnect layer of a semiconductor device may enable increased customization for the device layer and/or for the interconnect layer, while enabling the manufacturing of the device layer and of the interconnect layer to be modularized. In other words, the device layer may be paired with various options for interconnect layer layouts without affecting the performance, reliability, processing times, and/or complexity of the device layer. Bonding structures to implement hybrid bonding may be formed on the device layer, and on the interconnect layer, so that the bonding structures may be used to bond the semiconductor structures including the device layer and the interconnect layer together to form the semiconductor device.

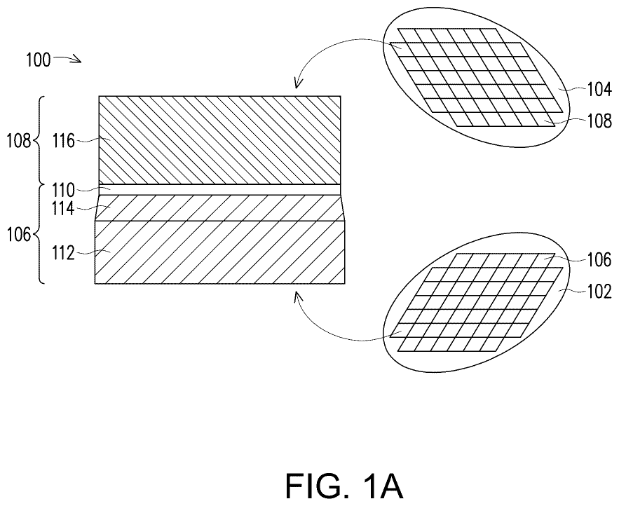

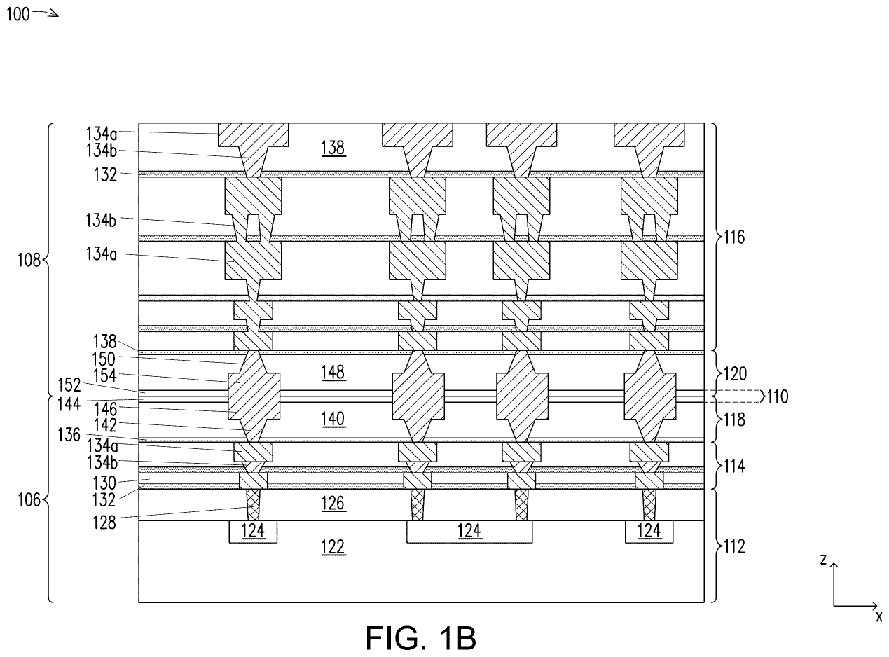

FIGS. 1A and 1B are diagrams of examples of semiconductor devices 100 described herein. As shown in FIG. 1A, the semiconductor device 100 is formed by bonding a first semiconductor wafer 102 and a second semiconductor wafer 104. For example, a bonding tool may be used to perform a bonding operation to bond the first semiconductor wafer 102 and the second semiconductor wafer 104 using a hybrid bonding technique, a direct bonding technique, a eutectic bonding technique, and/or another bonding technique. In the bonding operation, first semiconductor dies 106 on the first semiconductor wafer 102 are bonded with associated second semiconductor dies 108 on the second semiconductor wafer 104 to form semiconductor devices 100 (e.g., stacked semiconductor devices). The semiconductor devices 100 are then diced and packaged. Other processing steps may be performed to form the semiconductor devices 100.

As shown in FIG. 1A, the first semiconductor die 106 and the second semiconductor die 108 may be bonded at a bonding interface 110 such that the first semiconductor die 106 and the second semiconductor die 108 are stacked or vertically arranged in the semiconductor device 100. The first semiconductor die 106 may include an SoC die, such as a logic die, a central processing unit (CPU) die, a graphics processing unit (GPU) die, a digital signal processing (DSP) die, an application specific integrated circuit (ASIC) die, and/or another type of SoC die. Additionally and/or alternatively, the first semiconductor die 106 may include a memory die, an input/output (I/O) die, a pixel sensor die, and/or another type of semiconductor die. A memory die may include a static random access memory (SRAM) die, a dynamic random access memory (DRAM) die, a NAND die, a high bandwidth memory (HBM) die, and/or another type of memory die. The second semiconductor die 108 may include the same type of semiconductor die as the first semiconductor die 106, or may include a different type of semiconductor die.

As further shown in FIG. 1A, the first semiconductor die 106 may include a device layer 112, and an interconnect layer 114 above the device layer 112. The second semiconductor die 108 may include an interconnect layer 116 above the bonding interface 110. The bonding interface 110 may be located between the interconnect layers 114 and 116.

FIG. 1B illustrates a cross-sectional view of the semiconductor device 100 in which the details of the device layer 112, and the details of the interconnect layers 114 and 116 are shown. FIG. 1B further illustrates details of a bonding region 118 of the first semiconductor die 106 and a bonding region 120 of the second semiconductor die 108. The bonding region 118 may be included above the interconnect layer 114 of the first semiconductor die 106, and the bonding region 120 may be included below the interconnect layer 116 of the second semiconductor die 108. The bonding interface 110 may be located between the bonding region 118 and the bonding region 120.

As shown in FIG. 1B, the device layer 112 of the first semiconductor die 106 includes a substrate 122. The substrate 122 corresponds to a portion of the first semiconductor wafer 102 on which the first semiconductor die 106 is formed. The substrate 122 includes a silicon (Si) substrate, a substrate formed of a material including silicon, a III-V compound semiconductor material substrate such as gallium arsenide (GaAs), a silicon on insulator (SOI) substrate, or another type of semiconductor substrate.

The first semiconductor die 106 includes a device layer 112 in the substrate 122 and/or on the substrate. The device layer 112 may include active device(s), such as transistor(s), or passive device(s), such as lightguide(s), among other examples. Integrated circuit devices 124 may be included in and/or on the substrate 122 in the device layer 112 of the first semiconductor die 106. The integrated circuit devices 124 may include transistors (e.g., planar transistors, fin field effect transistors (finFETs), gate all around (GAA) transistors), pixel sensors, capacitors, resistors, inductors, photodetectors, transceivers, transmitters, receivers, optical circuits, and/or other types of semiconductor devices.

A dielectric layer 126 is included over the substrate 122. The dielectric layer 126 includes an interlayer dielectric (ILD) layer, an etch stop layer (ESL), and/or another type of dielectric layer. The dielectric layer 126 includes dielectric material(s) that enable various portions of the substrate 122 and/or the integrated circuit devices 124 to be selectively etched or protected from etching, and/or to electrically isolate the integrated circuit devices 124 in a device region. The dielectric layer 126 includes a silicon nitride (SiₓN_{y}), an oxide (e.g., a silicon oxide (SiOₓ) and/or another oxide material), and/or another type of dielectric material. Contacts 128 (e.g., source/drain contacts, gate contacts) may extend through the dielectric layer 126 and between the integrated circuit devices 124 and the interconnect layer 114. The contacts 128 may electrically connect the integrated circuit devices 124 to the interconnect layer 114. The contacts 128 may include vias, plugs, and/or another type of elongated electrically conductive structures. The contacts 128 may include tungsten (W), cobalt (Co), ruthenium (Ru), titanium (Ti), aluminum (Al), and/or gold (Au), among other electrically conductive materials.

An interconnect layer 114 of the first semiconductor die 106 may be included above the substrate 122, above the integrated circuit devices 124, and below the bonding region 118. An interconnect layer 116 of the second semiconductor die 108 may be included above the bonding region 120. The interconnect layer 114 and the interconnect layer 116 includes a plurality of dielectric layers that are arranged in a direction that is approximately perpendicular to the substrate 122. The dielectric layers may include ILD layers 130 and ESLs 132 that are arranged in an alternating manner. The ILD layers 130 may each include a low dielectric constant (low-k) oxide material such as a silicon oxide (SiOₓ) or undoped silicate glass (USG). Additionally and/or alternatively, the ILD layers 130 may each include a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 130 includes an extreme low-k (ELK) dielectric material having a dielectric constant that is less than approximately 2.5. Examples of ELK dielectric materials include carbon doped silicon oxide (C—SiOₓ), amorphous fluorinated carbon (a-CₓF_{y}), parylene, bis-benzocyclobutenes (BCB), polytetrafluoroethylene (PTFE), a silicon oxycarbide (SiOC) polymer, porous HSQ, porous methyl silsesquioxane (MSQ), porous polyarylether (PAE), and/or porous silicon oxide (SiOₓ), among other examples. The ESLs 132 may each include a silicon nitride (SiₓN_{y}), silicon carbide (SiC), silicon oxynitride (SiON), and/or another suitable dielectric material. In some implementations, an ILD layer 130 and an ESL 132 may include different dielectric materials to provide etch selectivity to enable various structures to be formed in the interconnect layer 114 and/or the interconnect layer 116. For example, the ILD layers 130 may each include a low-k dielectric material such as USG, and the ESLs 132 may each include a high-k dielectric material such as silicon nitride (SiₓN_{y}) or silicon carbide (SiC). Additionally and/or alternatively, two or more ESLs 132 may include different materials. For example, one or more first ESLs 132 may include silicon nitride (SiₓN_{y}), and one or more second ESLs 132 may include silicon carbide (SiC).

The interconnect layer 114 and interconnect layer 116 may each include a plurality of metallization structures 134a. The metallization structures 134a may be electrically coupled and/or physically coupled with one or more of the integrated circuit devices 124 in the device layer 112. The metallization structures 134a may be conductive structures that provide electrical routing that enables signals and/or power to be provided to and/or from the integrated circuit devices 124. The metallization structures 134a are vertically arranged in different layers and alternate in the z-direction (e.g., vertically alternate) with interconnect structures 134b, which are also vertically arranged in different layers.

The metallization structures 134a may include a combination of trenches, metallization layers, conductive traces, and/or other types of conductive structures. The interconnect structures 134b may include a combination of vias, interconnects, and/or other types of conductive structures. The metallization structures 134a and the interconnect structures 134b may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included between the dielectric layers of the interconnect layer 114 and/or interconnect layer 116, and the metallization structures 134a, and/or between the dielectric layers of the interconnect layer 114 and/or interconnect layer 116, and the interconnect structures 134b. The one or more liner layers may include barrier liners, adhesion liners, and/or another type of liners. Examples of materials for the one or more liners include tantalum nitride (TaN) and/or titanium nitride (TiN), among other examples.

The plurality of stacked metallization structures 134a may be referred to as M-layers. For example, a metal-0 (M0) layer may located at the bottom of the interconnect layer 114 and may be directly coupled with the device layer 112 (e.g., with the contacts 128 or interconnect structures of the integrated circuit devices 124 in the device layer 112), a metal-1 layer (M1) layer may be located above the M0 layer in the interconnect layer 114, a metal-2 layer (M2) layer may be located above the M1 layer in the interconnect layer 116, a metal-3 layer (M3) layer may be located above the M2 layer in the interconnect layer 116, and so on.

As further shown in FIG. 1B, the bonding region 118 may include a carbide layer 136 over and/or an ILD layer 130 of the interconnect layer 114, and the bonding region 120 may include a carbide layer 138 on an ILD layer 130 of the interconnect layer 116. The bonding region 118 may further include a dielectric layer 140 over and/or on the carbide layer 136. Bonding interconnect structures 142 extend through and/or are included in the carbide layer 136 and extend through and/or are included in the dielectric layer 140. The bonding interconnect structures 142 are electrically coupled and/or physically coupled with the metallization structures 134a.

A bonding dielectric layer 144 may be included over and/or on the dielectric layer 140. The bonding dielectric layer 144 may include a silicon oxynitride (SiON) and/or another suitable bonding dielectric material. Bonding pads 146 may extend through and/or are included in the dielectric layer 140, and the bonding dielectric layer 144.

The bonding region 120 may further include a dielectric layer 148 under the carbide layer 138. Bonding interconnect structures 150 extend through and/or are included in the carbide layer 138 and extend through and/or are included in the dielectric layer 148. The bonding interconnect structures 150 are electrically coupled and/or physically coupled with the metallization structures 134a.

The carbide layer 136 and the carbide layer 138 may be included in the bonding region 118 and the in the bonding region 120, respectively, as ESLs. The carbide layer 136 and the carbide layer 138 may include a carbon-containing dielectric material such as silicon carbide (SiC). The carbon-containing dielectric material of the carbide layer 136 and of the carbide layer 138 is harder than other dielectric materials such as silicon nitride (SiₓN_{y}) and silicon oxide (SiOₓ), which provides a closer match of thermal expansion and contraction coefficients between the carbide layer 136 and the bonding interconnect structures 142, and between the carbide layer 136 and the bonding interconnect structures 150 than other dielectric materials. Moreover, the carbon-containing dielectric material of the carbide layer 136 and of the carbide layer 138 reduces the likelihood of discontinuity formation (e.g., voids, cracks, delamination, peeling) in the bonding interconnect structures 142 and in the bonding interconnect structures 150 because of the increased adhesion with the metal material(s) (e.g., copper (Cu) and/or another metal material) of the bonding interconnect structures 142 and of the bonding interconnect structures 150 relative to other dielectric materials.

The dielectric layer 140 and the dielectric layer 148 may include a high density plasma (HDP) dielectric material and/or another suitable dielectric material. The bonding interconnect structures 142 and the bonding interconnect structures 150 may each include a via, an interconnect, a conductive column, a plug, and/or another type of conductive structure. The bonding interconnect structures 142 and the bonding interconnect structures 150 may each include one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

A bonding dielectric layer 152 may be included over and/or on the dielectric layer 148. Bonding pads 154 may extend through and/or are included in the dielectric layer 148, and the bonding dielectric layer 152. The bonding dielectric layer 152 may include a silicon oxynitride (SiON) and/or another suitable bonding dielectric material.

The bonding pads 146 are electrically coupled and/or physically coupled with the bonding interconnect structures 142, and the bonding pads 154 are electrically coupled and/or physically coupled with the bonding interconnect structures 150. The bonding pads 146 and the bonding pads 154 may each include a trench, a pad, a contact, and/or another type of conductive bonding structure. The bonding pads 146 and the bonding pads 154 may each include one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

At the bonding interface 110, the bonding dielectric layer 144 and the bonding dielectric layer 152 are bonded by a dielectric-to-dielectric bond. The bonding pads 146 and the bonding pads 154 are bonded by a metal-to-metal bond. The combination of the dielectric-to-dielectric bond and the metal-to-metal bond is referred to as a hybrid bond.

As can be seen in FIG. 1B, the interconnect structures 134b in the interconnect layer 116 are oriented in a same orientation direction with respect to the x-axis as the interconnect structures 134b in the interconnect layer 114. The x-axis is substantially parallel to a top surface of the substrate 122. The interconnect structures 134b in the interconnect layer 116 are also oriented in a same orientation direction with respect to the x-axis as the bonding interconnect structures 142 in the bonding region 118. For example, both the interconnect structures 134b in the interconnect layer 116 and the interconnect structures 134b in the interconnect layer 114 are tapered with a width in the x-direction decreasing in the downward z-direction. Similarly, both the interconnect structures 134b in the interconnect layer 116 and the bonding interconnect structures 142 in the bonding region 118 are tapered with a width in the x-direction decreasing in the downward z-direction.

The interconnect structures 134b in the interconnect layer 116 are oriented in a different orientation direction with respect to the x-axis from the bonding interconnect structures 150 in the bonding region 120. For example, the interconnect structures 134b in the interconnect layer 116 are tapered with a width in the x-direction decreasing in the downward z-direction, while the bonding interconnect structures 150 in the bonding region 120 are tapered with a width in the x-direction increasing in the downward z-direction. In other words, the interconnect structures 134b in the interconnect layer 116 are inverted with respect to the bonding interconnect structures 150 in the bonding region 120.

In some implementations, the first semiconductor die 106 is an active die including a device layer 112, and the second semiconductor die 108 is a passive die, where there is no functional integrated circuit (e.g., no device layer) above the interconnect layer 116. Alternatively, unlike system-on-integrated chip (SoIC) die stacking, the semiconductor device 100 is manufactured from a single die where portions of the interconnect layer (e.g., interconnect layer 114 and interconnect layer 116) of the single die are bonded together.

As indicated above, FIGS. 1A and 1B are provided as examples. Other examples may differ from what is described with regard to FIGS. 1A and 1B.

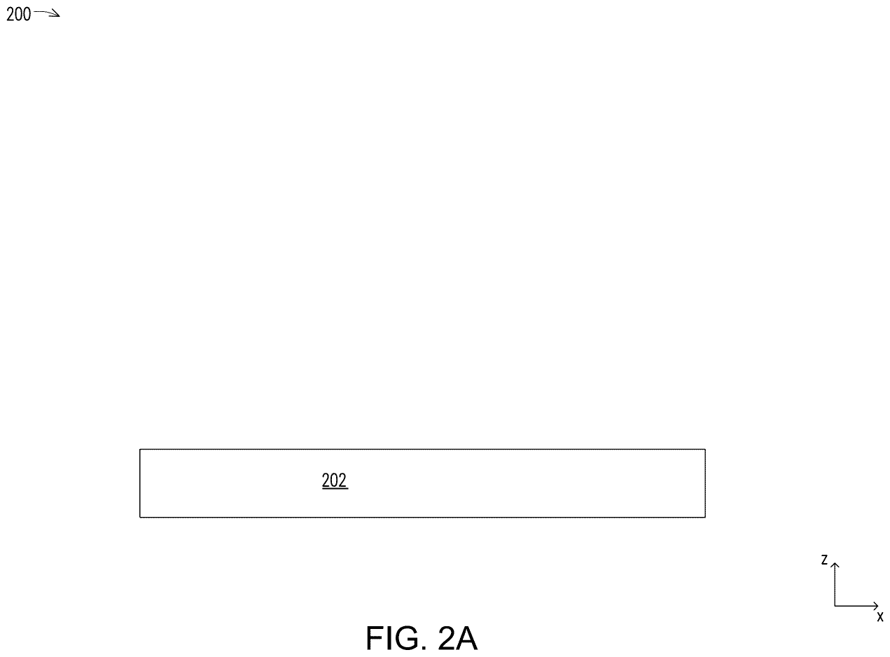

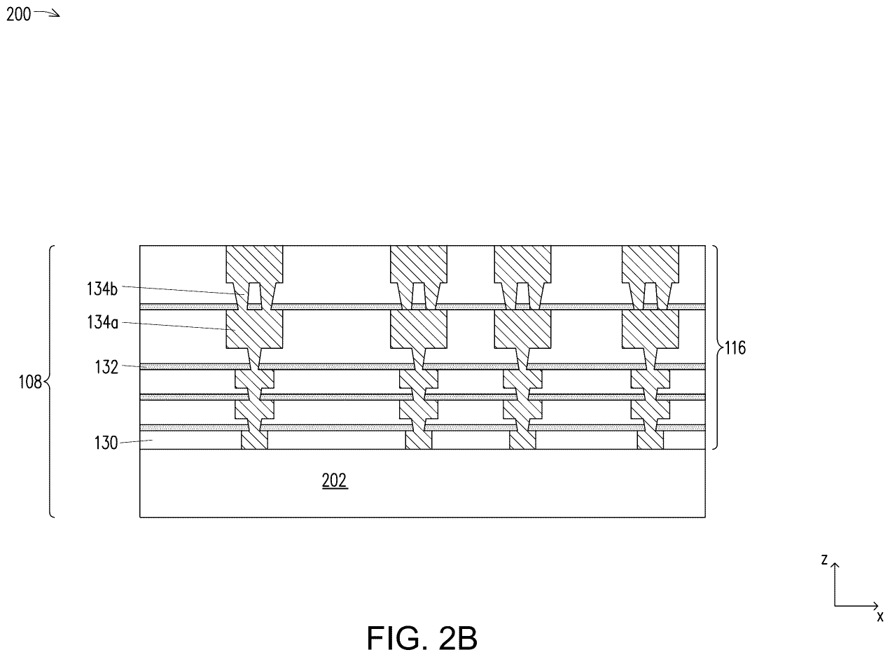

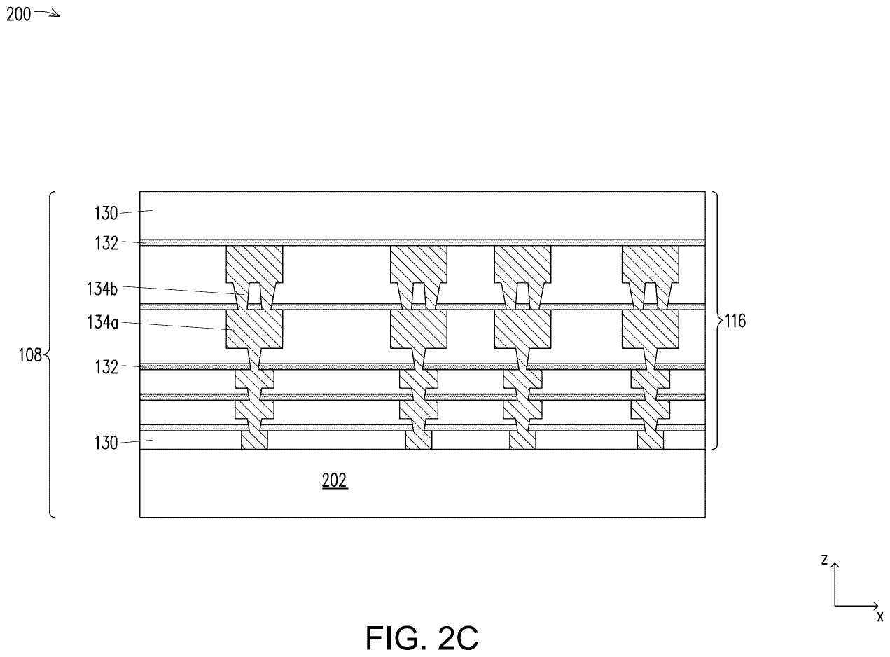

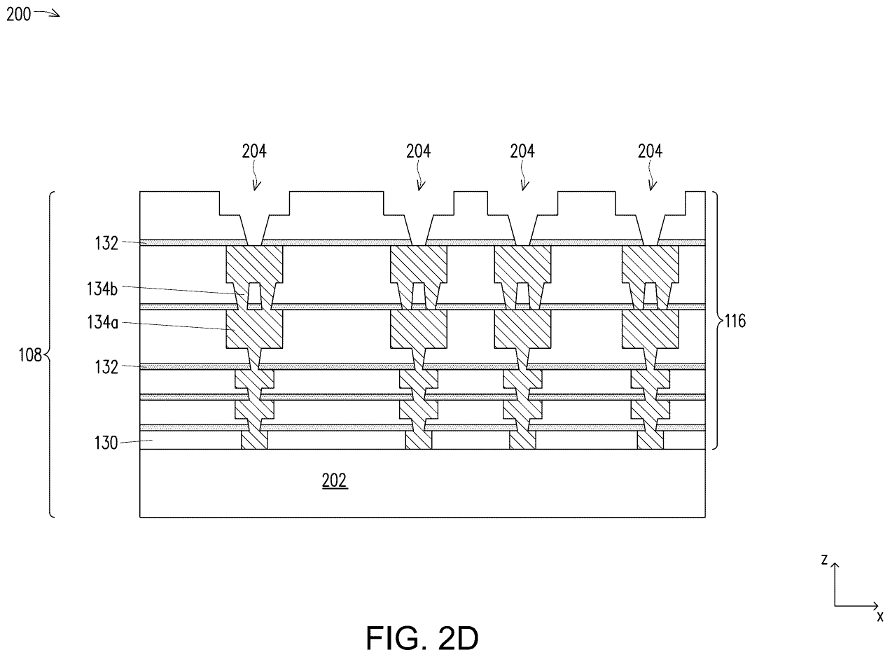

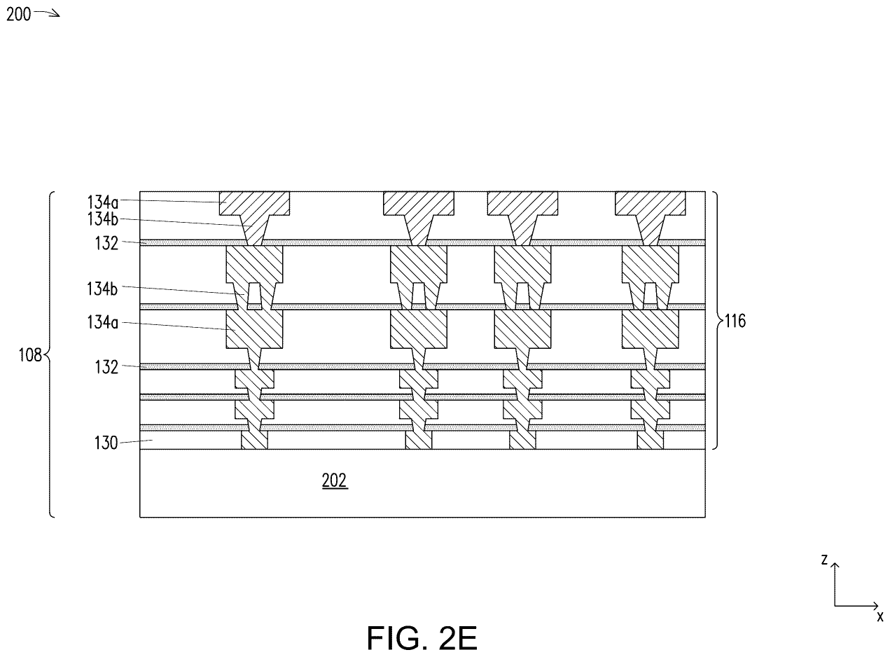

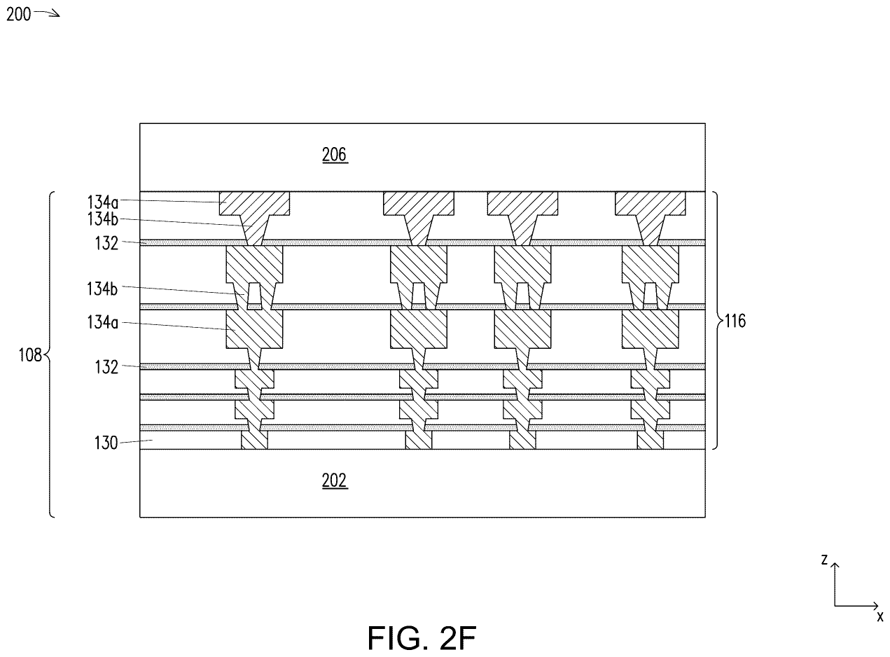

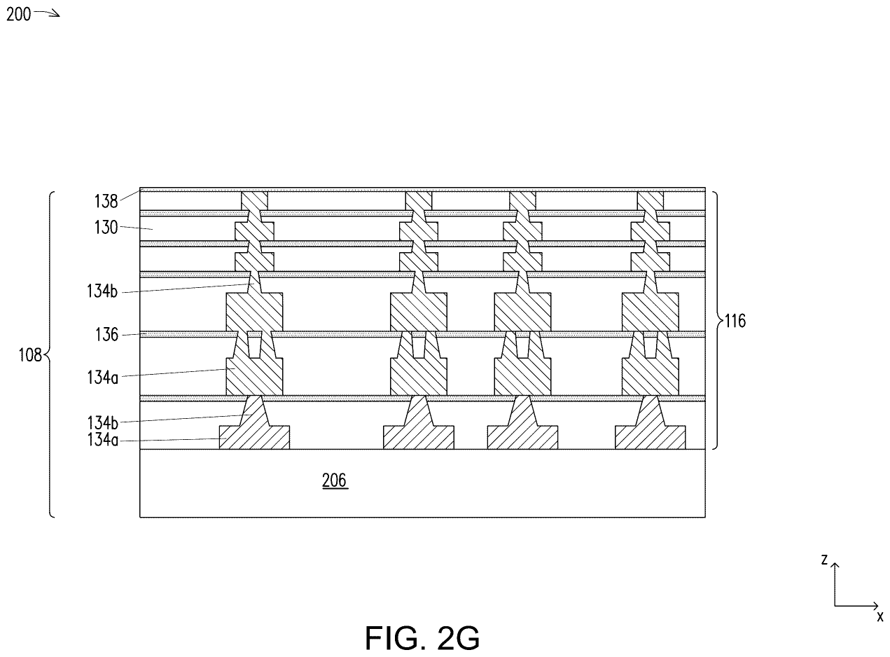

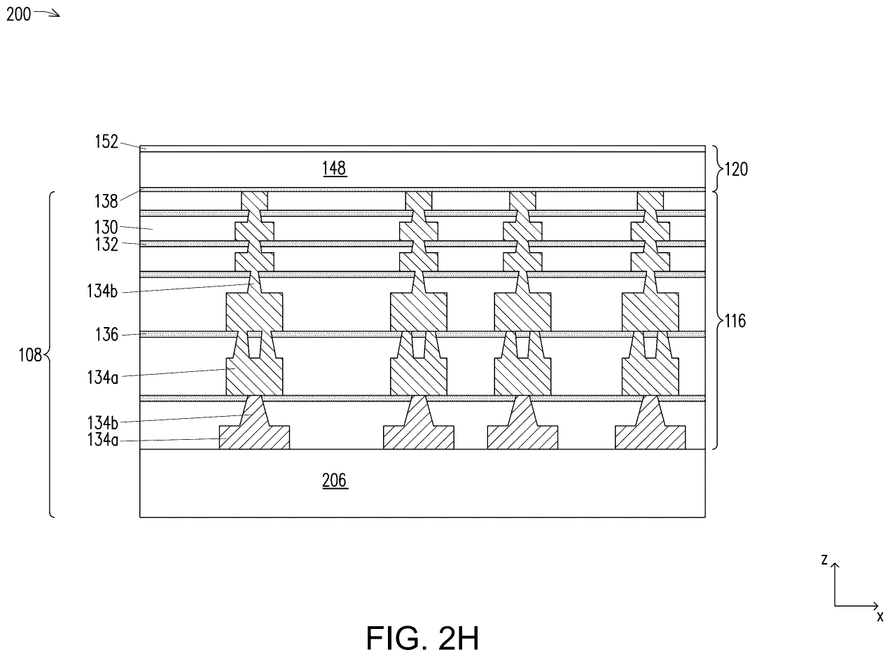

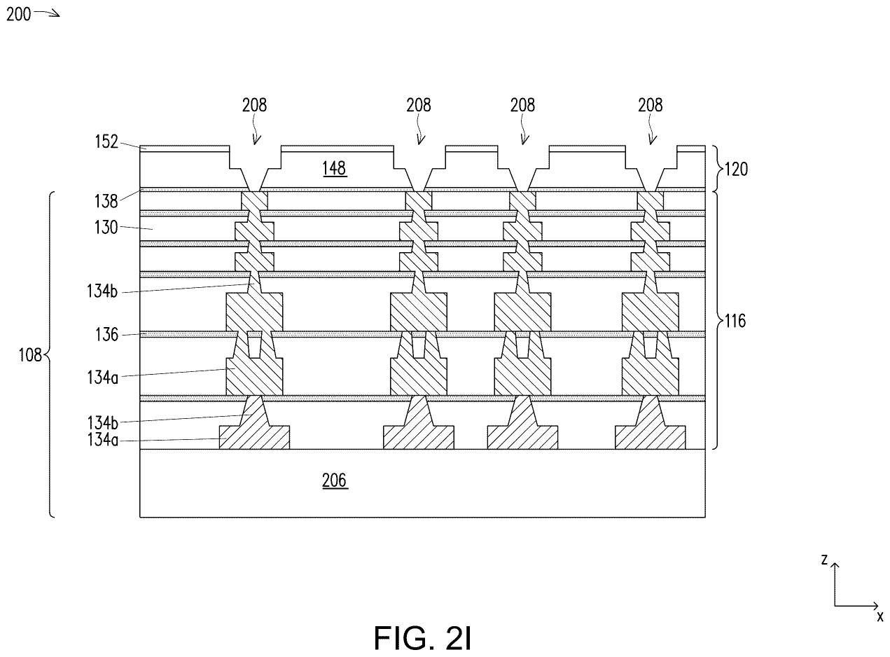

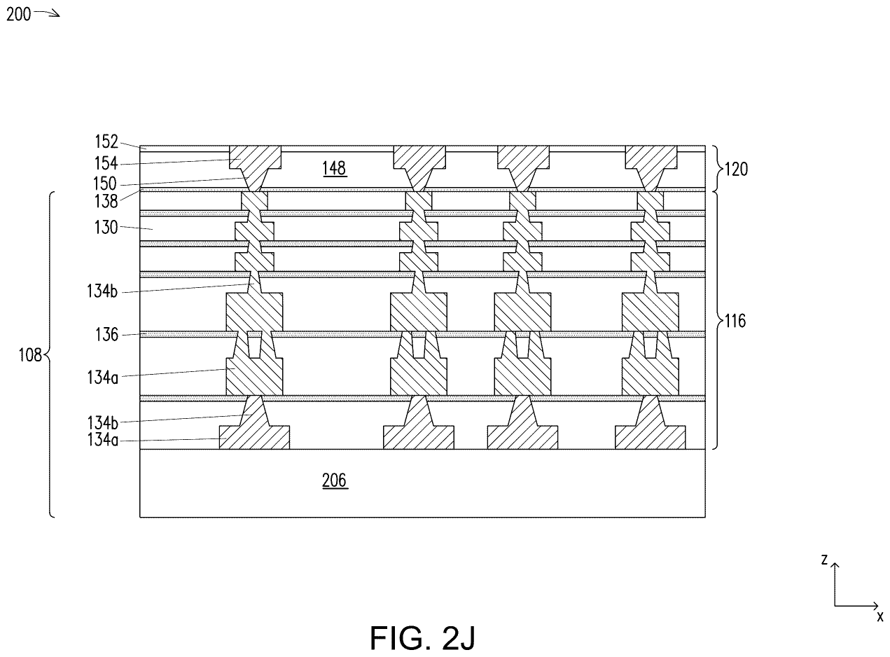

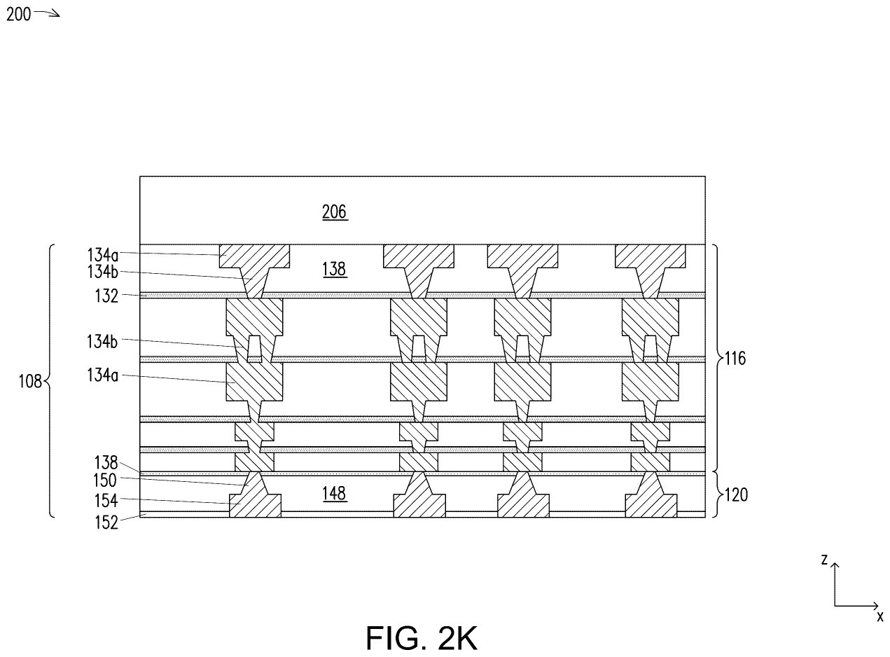

FIGS. 2A-2K are diagrams of an example implementation 200 of forming a semiconductor die described herein. In some implementations, one or more of the semiconductor processing tools and/or a wafer/die transport tool may be used to perform one or more of the semiconductor processing operations described in connection with FIGS. 2A-2K. In some implementations, one or more of the semiconductor processing operations described in connection with FIGS. 2A-2K may be performed using another semiconductor processing tool.

Turning to FIG. 2A, in connection with forming the second semiconductor die 108, a substrate 202 may be provided. The substrate 202 may be provided in the form of a semiconductor wafer such as a silicon (Si) wafer. The second semiconductor die 108 may be formed on the substrate 202 along with a plurality of other second semiconductor dies 108.

Referring to FIG. 2B, one or more deposition tools are used to deposit alternating layers of ILD layers 130 and ESLs 132 to form the interconnect layer 116 of the semiconductor device 100. In this way, the ILD layers 130 and ESLs 132 may be arranged in the z-direction in the semiconductor device 100. One or more deposition tools may be used to deposit each of the ILD layers 130 and each of the ESLs 132 using a physical vapor deposition (PVD) technique, an atomic layer deposition (ALD) technique, a chemical vapor deposition (CVD) technique, an oxidation technique, and/or another suitable deposition technique. In some implementations, a planarization tool may be used to planarize the ILD layers 130 and/or the ESLs 132 after the ILD layers 130 and/or the ESLs 132 are deposited.

As further shown in FIG. 2B, a deposition tool, an exposure tool, a developer tool, an etch tool, a planarization tool, a plating tool, and/or another semiconductor processing tool may be used to perform various operations to form the metallization structures 134a and to form the interconnect structures 134b in the interconnect layer 116 of the semiconductor device 100.

In some implementations, the interconnect layer 116 may be formed in a plurality of layers. For example, an ILD layer 130 and an ESL 132 may be formed (e.g., using one or more deposition tools and/or one or more planarization tools), recesses may be formed in and/or through the ILD layer 130 and the ESL 132 (e.g., using an exposure tool, a developer tool, and/or an etch tool), and a first layer of metallization structures 134a may be formed in the ILD layer 130 and the ESL 132 (e.g., using one or more deposition tools and/or one or more planarization tools). Another ILD layer 130 and another ESL 132 may be formed, and a first layer of interconnect structures 134b may be formed in the ILD layer 130 and the ESL 132. Additional layers of metallization structures 134a and interconnect structures 134b may be formed in a similar manner.

One or more deposition tools may be used to deposit the metallization structures 134a, and the interconnect structures 134b using a PVD technique, an ALD technique, a CVD technique, an electroplating technique (e.g., an electro-chemical plating technique), and/or another suitable deposition technique. In some implementations, a planarization tool may be used to planarize the metallization structures 134a, and/or the interconnect structures 134b after the metallization structures 134a, and/or the interconnect structures 134b are deposited.

As shown in FIG. 2C, an additional ESL 132 and an additional ILD layer 130 are deposited over a layer of the metallization structures 134a. Then, as shown in FIG. 2D, recesses 204 are formed in and/or through the ILD layer 130 and ESL 132. The top surfaces of the topmost metallization structures 134b in the interconnect layer 116 are exposed through the recesses 204. In some implementations, a dual damascene process is used to form the recesses 204. For example, and as shown in FIG. 2D, an interconnect structure (e.g., via) portion of the recesses 204 may be formed in and/or through the ILD layer 130 and ESL 132. In particular, the interconnect structure portion may be formed from a top surface of the ILD layer 130 through the ILD layer 130, and through the ESL 132. A deposition tool may be used to form a photoresist layer on the ILD layer 130. An exposure tool may be used to expose the photoresist layer to a radiation source to pattern the photoresist layer. A developer tool may be used to develop and remove portions of the photoresist layer to expose the pattern. An etch tool may be used to etch the ILD layer 130 and the ESL 132 to form the interconnect structure portion of the recesses 204. In some implementations, a photoresist removal tool removes the remaining portions of the photoresist layer (e.g., using a chemical stripper and/or another technique).

A trench portion of the recesses 204 may be formed in the ILD layer 130 above the interconnect structure portion. In particular, the trench portion may be formed from the top surface of the ILD layer 130 and into a portion of the ILD layer 130. A deposition tool may be used to form a photoresist layer on the ILD layer 130. An exposure tool may be used to expose the photoresist layer to a radiation source to pattern the photoresist layer. A developer tool may be used to develop and remove portions of the photoresist layer to expose the pattern. An etch tool may be used to etch the ILD layer 130 to form the trench portion of the recesses 204 in the ILD layer 130. In some implementations, a photoresist removal tool removes the remaining portions of the photoresist layer (e.g., using a chemical stripper and/or another technique).

An interconnect structure-first dual damascene procedure can be performed in which the recesses 204 are formed by forming the interconnect structure portion before forming the trench portion. In some implementations, a trench-first dual damascene procedure can be performed in which the recesses 204 are formed by forming the trench portion before forming the interconnect structure portion.

As shown in FIG. 2E, the interconnect structures 134b are formed in the interconnect structure portion of the recesses 204 such that the interconnect structures 134b land on (and are electrically coupled and/or physically coupled with) the topmost metallization structures 134a. Additional metallization structures 134a are formed in the trench portion of the recesses 204 on the interconnect structures 134b. The metallization structures 134a and the interconnect structures 134b may include one or more liner layers and a conductive fill layer. The one or more liner layers may include adhesion layers, barrier layers, and/or another type of liners that are conformally deposited on the sidewalls and/or the bottom surfaces of the recesses 204. Examples of materials for the one or more liner layers include tantalum nitride (TaN), titanium nitride (TiN), ruthenium (Ru), cobalt (Co), and/or ruthenium oxide (RuOₓ), among other examples. A deposition tool may be used to deposit the one or more liner layers using a PVD technique, an ALD technique, a CVD technique, and/or another suitable deposition technique.

Following the processing in FIG. 2E to form the interconnect layer 116, the structure in FIG. 2E may be exposed ultraviolet (UV) light for a designated period of time to reduce charge that may have been built up during, for example, plasma-based processing (e.g., etching) to form recesses (e.g., recesses 204) in the ILD layers 130 and ESLs 132 for metallization structures 134a and/or interconnect structures 134b. The UV light in the UV curing operation may have a wavelength included in a range of approximately 100 nanometers to approximately 400 nanometers. Exposure to the of the structure to the UV light may neutralize charges which may have been generated during processing to form the interconnect layer 116. As a result, the presence of damage-inducing charges, which may cause damage to dielectric films in the device layer 112 (e.g., gate oxide films), may be reduced and/or prevented prior to bonding the semiconductor structure including the interconnect layer 116 (e.g., the second semiconductor die 108) to the semiconductor structure including the device layer 112 (e.g., the first semiconductor die 106).

As shown in FIG. 2F, a substrate 206 is attached to the top of the structure from FIG. 2E. The substrate 206 can be, for example, a carrier wafer. In some implementations, the substrate 206 may be, for example, a silicon nitride (SiₓN_{y}) wafer that is bonded to the top surface of the ILD layer 130 using a silicon oxynitride (SiON) bond. The silicon oxynitride (SiON) bond may be formed between the silicon nitride (SiₓN_{y}) of the substrate 206 and silicon oxide (SiOₓ) of the ILD layer 130. Alternatively, the substrate 206 may be a glass substrate that is attached to the top of the structure from FIG. 2E by an adhesive. The adhesive may be, for example, a polymeric material, such as a polyimide-based material, and/or a thermoplastic polymer.

The resulting structure is flipped (e.g., rotated 180 degrees) using a wafer/die transport tool so that the substrate 202 is at a top of the structure instead of a bottom of the structure in the z-direction, and the substrate 206 is at a bottom of the structure instead of a top of the structure in the z-direction. The substrate 206 can be attached to a wafer/die transport tool to perform the rotation.

As shown in FIG. 2G, following the flipping process, the substrate 202 can be removed using, for example, a wafer grinding operation and/or an etch operation. The removal of the substrate 202 exposes the ILD layer 130 and the metallization structures 134a that are at the top of the structure following the flipping process. Then, the carbide layer 138 may be formed over and/or on the exposed ILD layer 130. The carbide layer 138 may also cover the exposed metallization structures 134a. A deposition tool may be used to deposit the carbide layer 138 using a PVD technique, an ALD technique, a CVD technique, and/or another suitable deposition technique. In some implementations, a planarization tool may be used to planarize the carbide layer 138 after the carbide layer 138 is deposited.

As shown in FIG. 2H, the dielectric layer 148 is deposited over and/or on the carbide layer 138. A deposition tool may be used to deposit the dielectric layer 148 using a PVD technique, an ALD technique, a CVD technique, an oxidation technique, and/or another suitable deposition technique. In some implementations, the planarization tool may be used to planarize the dielectric layer 148 after the dielectric layer 148 is deposited.

The bonding dielectric layer 152 is deposited over and/or on the dielectric layer 148. A deposition tool may be used to deposit the bonding dielectric layer 152 using a PVD technique, an ALD technique, a CVD technique, an oxidation technique, and/or another suitable deposition technique. In some implementations, the planarization tool may be used to planarize the bonding dielectric layer 152 after the bonding dielectric layer 152 is deposited.

As shown in FIG. 2I, recesses 208 are formed in and/or through the bonding dielectric layer 152, the dielectric layer 148, and the carbide layer 138. Top surfaces of the metallization structures 134a under the carbide layer 138 are exposed through the recesses 208. In some implementations, a dual damascene process is used to form the recesses 208. For example, an interconnect structure portion of the recesses 208 may be formed from a top surface of the bonding dielectric layer 152 through the bonding dielectric layer 152, the dielectric layer 148, and the carbide layer 138. A deposition tool may be used to form a photoresist layer on the bonding dielectric layer 152. An exposure tool may be used to expose the photoresist layer to a radiation source to pattern the photoresist layer. A developer tool may be used to develop and remove portions of the photoresist layer to expose the pattern. An etch tool may be used to etch the bonding dielectric layer 152, the dielectric layer 148, and the carbide layer 138 to form the interconnect structure portion of the recesses 208. In some implementations, a photoresist removal tool removes the remaining portions of the photoresist layer (e.g., using a chemical stripper and/or another technique).

A trench portion of the recesses 208 may be formed in the bonding dielectric layer 152 and in the dielectric layer 148 above the interconnect structure portion. In particular, the trench portion may be formed from the top surface of the bonding dielectric layer 152 and through the bonding dielectric layer 152, and the dielectric layer 148. A deposition tool may be used to form a photoresist layer on the bonding dielectric layer 152. An exposure tool may be used to expose the photoresist layer to a radiation source to pattern the photoresist layer. A developer tool may be used to develop and remove portions of the photoresist layer to expose the pattern. An etch tool may be used to etch the bonding dielectric layer 152, and the dielectric layer 148 to form the trench portion of the recesses 208 in the bonding dielectric layer 152, and the dielectric layer 148. In some implementations, a photoresist removal tool removes the remaining portions of the photoresist layer (e.g., using a chemical stripper and/or another technique).

An interconnect structure-first dual damascene procedure in which the recesses 208 are formed by forming the interconnect structure portion before forming the trench portion may be used. In some implementations, a trench-first dual damascene procedure in which the recesses 208 are formed by forming the trench portion before forming the interconnect structure portion may be used.

As shown in FIG. 2J, the bonding interconnect structures 150 are formed in the interconnect structure portion of the recesses 208 such that the bonding interconnect structures 150 land on (and are electrically coupled and/or physically coupled with) the metallization structures 134a under the carbide layer 138. The bonding pads 154 are formed in the trench portion of the recesses 208 on the bonding interconnect structures 150. The bonding interconnect structures 150 and the bonding pads 154 may include one or more liner layers and a conductive fill layer. The one or more liner layers may include adhesion layers, barrier layers, and/or another type of liners that are conformally deposited on the sidewalls and/or the bottom surfaces of the recesses 208. The bonding interconnect structures 150 and the bonding pads 154 may include one or more electrically conductive materials such as copper (Cu), tungsten (W), cobalt (Co), ruthenium (Ru), titanium (Ti), aluminum (Al), gold (Au), and/or a combination thereof, among other examples of electrically conductive materials. Examples of materials for the one or more liner layers include tantalum nitride (TaN), titanium nitride (TiN), ruthenium (Ru), cobalt (Co), and/or ruthenium oxide (RuOₓ), among other examples.

A deposition tool may be used to deposit the one or more liner layers using a PVD technique, an ALD technique, a CVD technique, and/or another suitable deposition technique. A deposition tool and/or a plating tool may be used to deposit the bonding interconnect structures 150 and the bonding pads 154 using a CVD technique, a PVD technique, an ALD technique, an electroplating technique, and/or another suitable deposition technique. In some implementations, a seed layer is first deposited, and a bonding interconnect structure 150 and/or a bonding pad 154 are deposited on the seed layer. In some implementations, a planarization tool is used to planarize the bonding pads 154 after the bonding pads 154 are deposited.

In some implementations, an annealing operation may be performed to reflow the conductive material of the bonding interconnect structures 150 and/or of the bonding pads 154 to remove voids in the bonding interconnect structures 150 and/or in the bonding pads 154. The carbon-containing dielectric material of the carbide layer 138 is harder than other dielectric materials such as silicon nitride (SiₓN_{y}) and silicon oxide (SiOₓ), which provides a closer match of thermal expansion and contraction coefficients between the carbide layer 138 and the bonding interconnect structures 150 than other dielectric materials. This reduces the magnitude of and/or the likelihood of stress migration between the bonding interconnect structures 150 and the carbide layer 138, which reduces the likelihood of discontinuity formation (e.g., voids, cracks, delamination, peeling) in the bonding interconnect structures 150.

In some implementations, following the processing in FIG. 2J to form the bonding region 120, the structure in FIG. 2J may be exposed ultraviolet (UV) light for a designated period of time to reduce charge that may have been built up during, for example, plasma-based processing (e.g., etching) to form recesses (e.g., recesses 208) in the bonding dielectric layer 152, the dielectric layer 148 and the carbide layer 138 for the bonding interconnect structures 150 and/or the bonding pads 154. This UV curing operation can be performed in addition to, or as an alternative to the UV curing operation described in connection with FIG. 2E, and may be the same or similar to the UV curing operation described in connection with FIG. 2E.

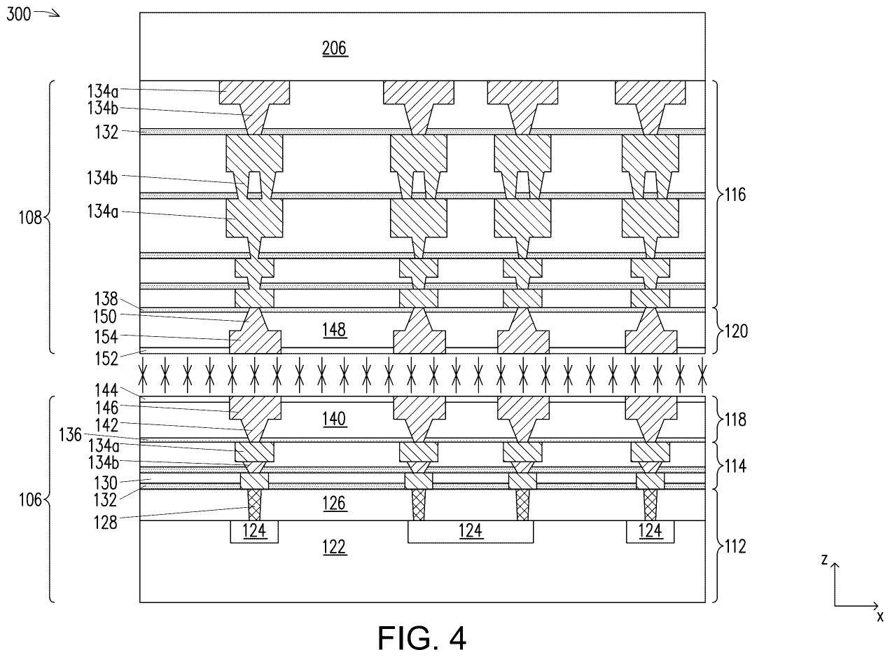

As shown in FIG. 2K, the resulting structure is flipped (e.g., rotated 180 degrees) using a wafer/die transport tool so that the substrate 206 is at a top of the structure instead of a bottom of the structure in the z-direction, and the bonding region 120 is at a bottom of the structure instead of a top of the structure in the z-direction. The substrate 206 can be attached to a wafer/die transport tool to perform the rotation. Following the flipping process, as described in more detail in connection with FIG. 4, a bonding operation to the first semiconductor die 106 is performed

As indicated above, FIGS. 2A-2K are provided as an example. Other examples may differ from what is described with regard to FIGS. 2A-2K.

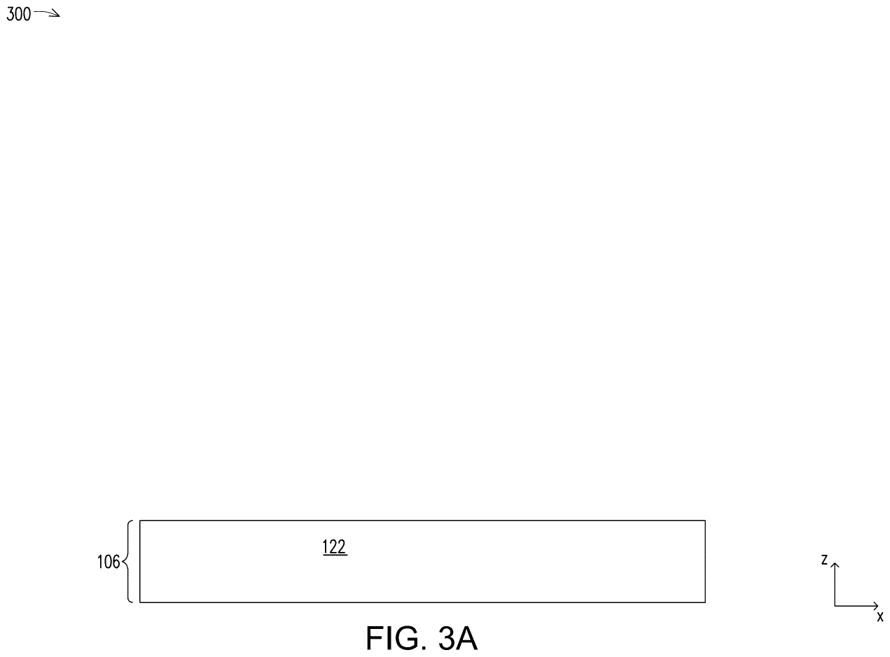

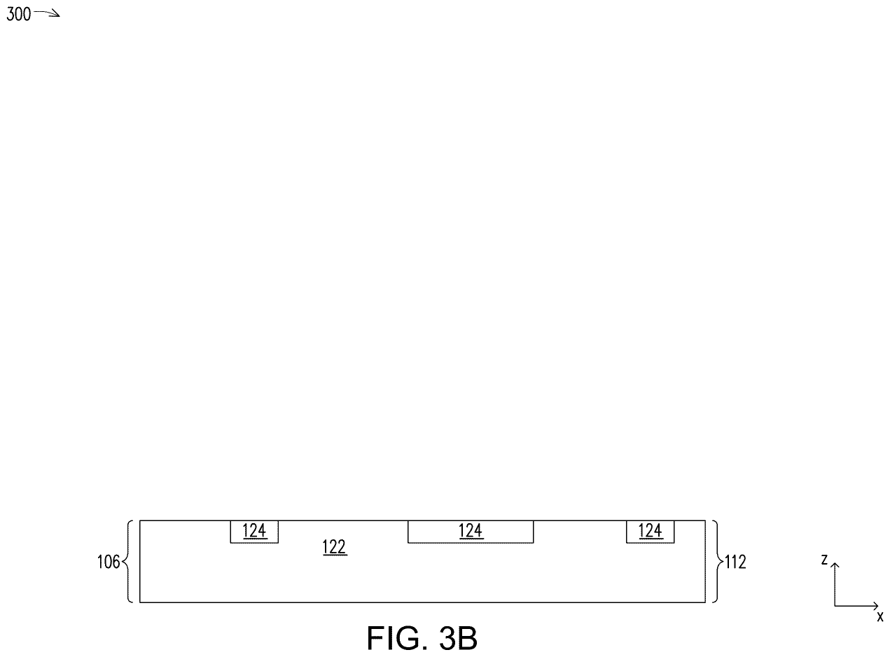

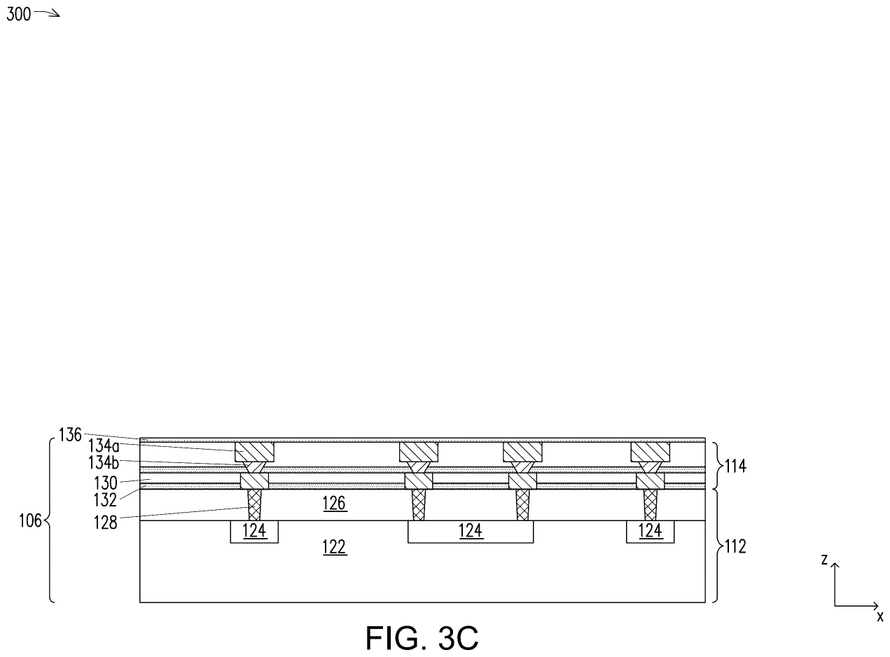

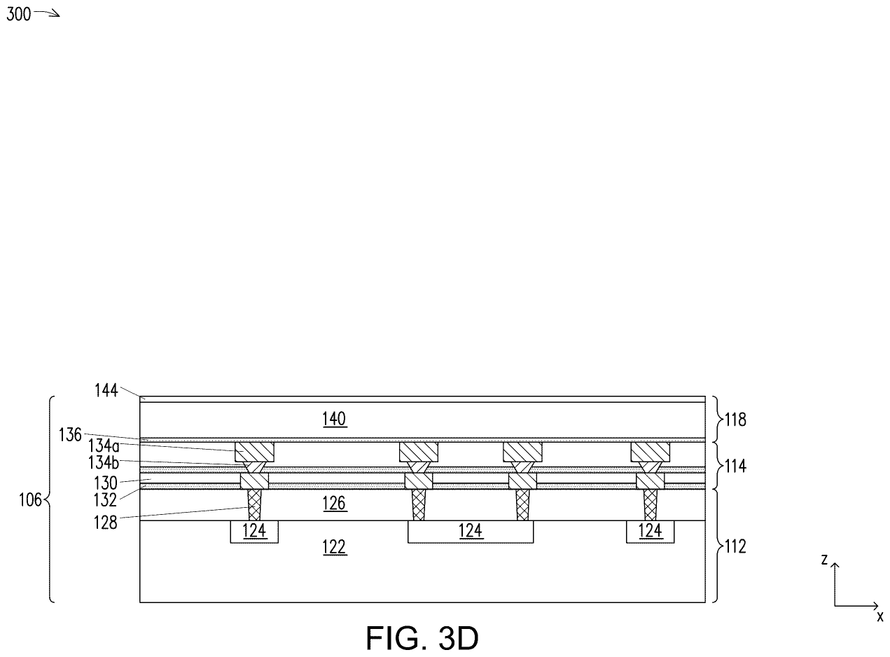

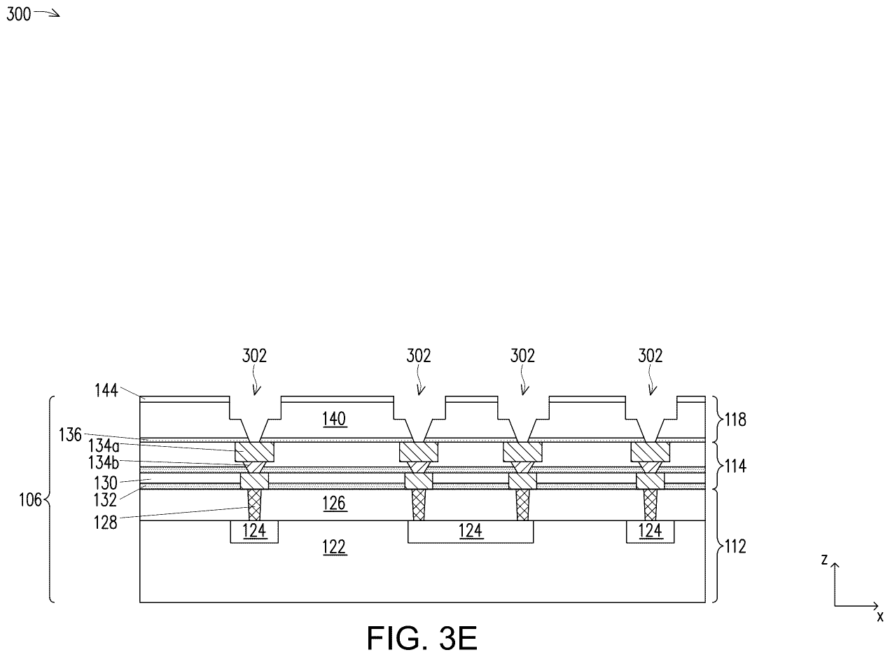

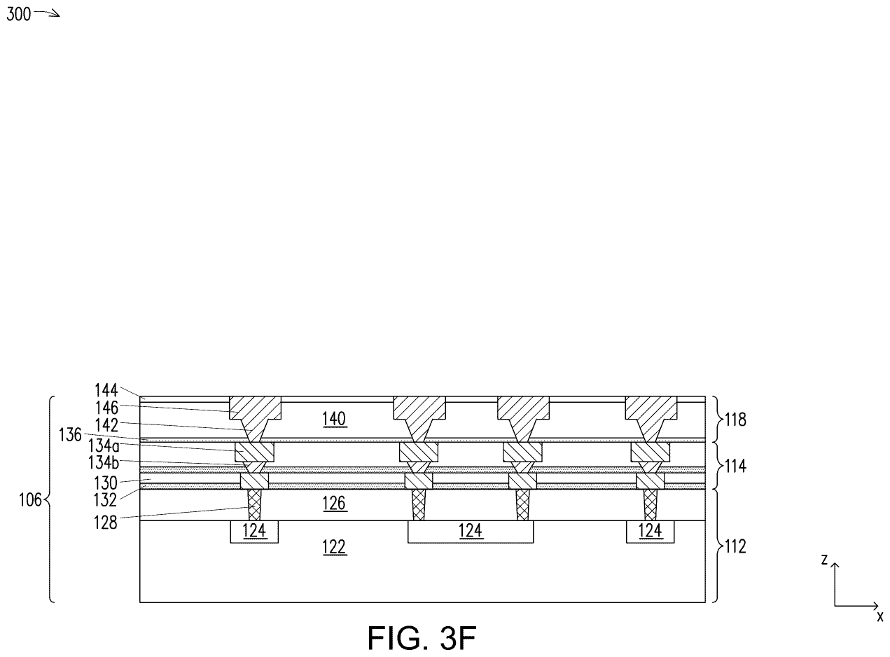

FIGS. 3A-3F are diagrams of an example implementation 300 of forming a semiconductor die described herein. In some implementations, one or more of the semiconductor processing tools and/or a wafer/die transport tool may be used to perform one or more of the semiconductor processing operations described in connection with FIGS. 3A-3F. In some implementations, one or more of the semiconductor processing operations described in connection with FIGS. 3A-3F may be performed using another semiconductor processing tool.

Turning to FIG. 3A, in connection with forming the first semiconductor die 106, a substrate 122 may be provided. The substrate 122 may be provided in the form of a semiconductor wafer such as a silicon (Si) wafer. The first semiconductor die 106 may be formed on the substrate 122 along with a plurality of other first semiconductor dies 106.

Referring to FIG. 3B, the integrated circuit devices 124 may be formed in and/or on the substrate 122 in the device layer 112 of the first semiconductor die 106. One or more of semiconductor processing tools may be used to form one or more portions of the integrated circuit devices 124. For example, a deposition tool may be used to perform various deposition operations to deposit layers of the integrated circuit devices 124, and/or to deposit photoresist layers for etching the substrate 122 and/or portions of the deposited layers. As another example, an exposure tool may be used to expose the photoresist layers to form patterns in the photoresist layers. As another example, a developer tool may develop the patterns in the photoresist layers. As another example, an etch tool may be used to etch the substrate 122 and/or portions of the deposited layers to form the integrated circuit devices 124. As another example, a planarization tool may be used to planarize portions of the integrated circuit devices 124. As another example, a plating tool may be used to deposit metal structures and/or layers of the integrated circuit devices 124.

As shown in FIG. 3C, a deposition tool is used to deposit the dielectric layer 126 over and/or on the substrate 122 and over and/or on the integrated circuit devices 124. One or more deposition tools is also used to deposit alternating layers of ESLs 132 and ILD layers 130 of the interconnect layer 114 of the first semiconductor die 106. In this way, the ILD layers 130 and ESLs 132 may be arranged in the z-direction in the semiconductor device 100. The one or more deposition tools may be used to deposit each of the ILD layers 130 and each of the ESLs 132 using a PVD technique, an ALD technique, a CVD technique, an oxidation technique, and/or another suitable deposition technique. In some implementations, a planarization tool may be used to planarize the ILD layers 130 and/or the ESLs 132 after the ILD layers 130 and/or the ESLs 132 are deposited.

A deposition tool, an exposure tool, a developer tool, an etch tool, a planarization tool, and/or a plating tool are used to perform various operations to form the contacts 128 in the device layer 112, and the metallization structures 134a and interconnect structures 134b in the interconnect layer 114 of the first semiconductor die 106. The contacts 128 may be included in the dielectric layer 126, and may be physically and/or electrically coupled to the integrated circuit devices 124. The metallization structures 134a and interconnect structures 134b may be included in the ILD layers 130 and/or the ESLs 132, and may be electrically coupled to the integrated circuit devices 124 in the device layer 112 through the contacts 128.

In some implementations, the interconnect layer 114 may be formed in a plurality of layers. For example, an ILD layer 130 and an ESL 132 may be formed (e.g., using one or more deposition tools and/or one or more planarization tools), recesses may be formed in and/or through the ILD layer 130 and the ESL 132 (e.g., using an exposure tool, a developer tool, and/or an etch tool), and a first layer of metallization structures 134a may be formed in the ILD layer 130 and the ESL 132 (e.g., using one or more deposition tools and/or one or more planarization tools). Another ILD layer 130 and another ESL 132 may be formed, and a first layer of interconnect structures 134b may be formed in the ILD layer 130 and the ESL 132. Additional layers of metallization structures 134a and interconnect structures 134b may be formed in a similar manner.

One or more deposition tools may be used to deposit the contacts 128, metallization structures 134a, and the interconnect structures 134b using a PVD technique, an ALD technique, a CVD technique, an electroplating technique (e.g., an electro-chemical plating technique), and/or another suitable deposition technique. In some implementations, a planarization tool may be used to planarize the contacts 128, the metallization structures 134a, and/or the interconnect structures 134b after the contacts 128, the metallization structures 134a, and/or the interconnect structures 134b are deposited.

The carbide layer 136 may be formed over and/or on the topmost ILD layer 130. The carbide layer 136 may also cover the exposed metallization structures 134a. A deposition tool may be used to deposit the carbide layer 136 using a PVD technique, an ALD technique, a CVD technique, and/or another suitable deposition technique. In some implementations, a planarization tool may be used to planarize the carbide layer 136 after the carbide layer 136 is deposited.

As shown in FIG. 3D, the dielectric layer 140 is deposited over and/or on the carbide layer 136. A deposition tool may be used to deposit the dielectric layer 140 using a PVD technique, an ALD technique, a CVD technique, an oxidation technique, and/or another suitable deposition technique. In some implementations, the planarization tool may be used to planarize the dielectric layer 140 after the dielectric layer 140 is deposited.

The bonding dielectric layer 144 is deposited over and/or on the dielectric layer 140. A deposition tool may be used to deposit the bonding dielectric layer 144 using a PVD technique, an ALD technique, a CVD technique, an oxidation technique, and/or another suitable deposition technique. In some implementations, the planarization tool may be used to planarize the bonding dielectric layer 144 after the bonding dielectric layer 144 is deposited.

As shown in FIG. 3E, recesses 302 are formed in and/or through the bonding dielectric layer 144, the dielectric layer 140, and the carbide layer 136. Top surfaces of the metallization structures 134a under the carbide layer 136 are exposed through the recesses 302. In some implementations, a dual damascene process is used to form the recesses 302. For example, an interconnect structure portion of the recesses 302 may be formed from a top surface of the bonding dielectric layer 144 through the bonding dielectric layer 144, the dielectric layer 140, and the carbide layer 136. A deposition tool may be used to form a photoresist layer on the bonding dielectric layer 144. An exposure tool may be used to expose the photoresist layer to a radiation source to pattern the photoresist layer. A developer tool may be used to develop and remove portions of the photoresist layer to expose the pattern. An etch tool may be used to etch the bonding dielectric layer 144, the dielectric layer 140, and the carbide layer 136 to form the interconnect structure portion of the recesses 302. In some implementations, a photoresist removal tool removes the remaining portions of the photoresist layer (e.g., using a chemical stripper and/or another technique).

A trench portion of the recesses 302 may be formed in the bonding dielectric layer 144 and in the dielectric layer 140 above the interconnect structure portion. In particular, the trench portion may be formed from the top surface of the bonding dielectric layer 144 and through the bonding dielectric layer 144, and the dielectric layer 140. A deposition tool may be used to form a photoresist layer on the bonding dielectric layer 144. An exposure tool may be used to expose the photoresist layer to a radiation source to pattern the photoresist layer. A developer tool may be used to develop and remove portions of the photoresist layer to expose the pattern. An etch tool may be used to etch the bonding dielectric layer 144, and the dielectric layer 140 to form the trench portion of the recesses 302 in the bonding dielectric layer 144, and the dielectric layer 140. In some implementations, a photoresist removal tool removes the remaining portions of the photoresist layer (e.g., using a chemical stripper and/or another technique).

An interconnect structure-first dual damascene procedure in which the recesses 302 are formed by forming the interconnect structure portion before forming the trench portion may be used. In some implementations, a trench-first dual damascene procedure in which the recesses 302 are formed by forming the trench portion before forming the interconnect structure portion may be used.

As shown in FIG. 3F, the bonding interconnect structures 142 are formed in the interconnect structure portion of the recesses 302 such that the bonding interconnect structures 142 land on (and are electrically coupled and/or physically coupled with) the metallization structures 134a under the carbide layer 136. The bonding pads 146 are formed in the trench portion of the recesses 302 on the bonding interconnect structures 142. The bonding interconnect structures 142 and the bonding pads 146 may include one or more liner layers and a conductive fill layer. The one or more liner layers may include adhesion layers, barrier layers, and/or another type of liners that are conformally deposited on the sidewalls and/or the bottom surfaces of the recesses 302. The bonding interconnect structures 142 and the bonding pads 146 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. Examples of materials for the one or more liner layers include tantalum nitride (TaN), titanium nitride (TiN), ruthenium (Ru), cobalt (Co), and/or ruthenium oxide (RuOₓ), among other examples.

A deposition tool may be used to deposit the one or more liner layers using a PVD technique, an ALD technique, a CVD technique, and/or another suitable deposition technique. A deposition tool and/or a plating tool may be used to deposit the bonding interconnect structures 142 and the bonding pads 146 using a CVD technique, a PVD technique, an ALD technique, an electroplating technique, and/or another suitable deposition technique. In some implementations, a seed layer is first deposited, and a bonding interconnect structure 142 and/or a bonding pad 146 are deposited on the seed layer. In some implementations, a planarization tool is used to planarize the bonding pads 146 after the bonding pads 146 are deposited.

In some implementations, an annealing operation may be performed to reflow the conductive material of the bonding interconnect structures 142 and/or of the bonding pads 146 to remove voids in the bonding interconnect structures 142 and/or in the bonding pads 146. The carbon-containing dielectric material of the carbide layer 136 is harder than other dielectric materials such as silicon nitride (SiₓN_{y}) and silicon oxide (SiOₓ), which provides a closer match of thermal expansion and contraction coefficients between the carbide layer 136 and the bonding interconnect structures 142 than other dielectric materials. This reduces the magnitude of and/or the likelihood of stress migration between the bonding interconnect structures 142 and the carbide layer 136, which reduces the likelihood of discontinuity formation (e.g., voids, cracks, delamination, peeling) in the bonding interconnect structures 142.

As indicated above, FIGS. 3A-3F are provided as an example. Other examples may differ from what is described with regard to FIGS. 3A-3F.

FIG. 4 is a diagram of an example implementation 400 of forming a semiconductor device 100 described herein. In particular, the example implementation 400 includes an example of bonding the first semiconductor die 106 and the second semiconductor die 108 to form the semiconductor device 100. In some implementations, one or more of the semiconductor processing tools 1 and/or a wafer/die transport tool may be used to perform one or more of the semiconductor processing operations described in connection with FIG. 4. In some implementations, one or more of the semiconductor processing operations described in connection with FIG. 4 may be performed using another semiconductor processing tool.

As shown in FIG. 4, a bonding operation is performed to bond the first semiconductor die 106 and the second semiconductor die 108 at the bonding interface 110 such that the first semiconductor die 106 and the second semiconductor die 108 are vertically arranged or stacked. The first semiconductor die 106 and the second semiconductor die 108 may be vertically arranged or stacked in a wafer on wafer (WoW) configuration, a die on wafer configuration, a die on die configuration, and/or another direct bonding configuration. A bonding tool may perform a bonding operation to bond the first semiconductor die 106 and the second semiconductor die 108 at the bonding interface 110. The bonding operation may include forming a direct bond between the first semiconductor die 106 and the second semiconductor die 108 through the physical connection of the bonding pads 146 and 154, and the physical connection of the bonding dielectric layers 144 and 152. At the bonding interface 110, a direct metal-to-metal bond is formed between the bonding pads 146 and 154, and a direct dielectric-to-dielectric bond is formed between the bonding dielectric layers 144 and 152. Accordingly, the bonding operation may be referred to as a hybrid bonding operation. The semiconductor device 100 shown in FIG. 1B may be formed as a result of the bonding operation.

In some implementations, the first semiconductor die 106 and the second semiconductor die 108 are bonded as part of bonding the first semiconductor wafer 102 and the second semiconductor wafer 104 in the bonding operation. Accordingly, the semiconductor device 100 may be diced or cut from the bonded first semiconductor wafer 102 and the second semiconductor wafer 104 and packaged.

Prior to, or following the bonding operation, the substrate 206 may be removed from the top of the second semiconductor die 108. The substrate 206 can be removed using, for example, a wafer grinding operation and/or an etch operation. The removal of the substrate 206 exposes the ILD layer 130 and the metallization structures 134a that are at the top of the structure.

As indicated above, FIG. 4 is provided as an example. Other examples may differ from what is described with regard to FIG. 4.

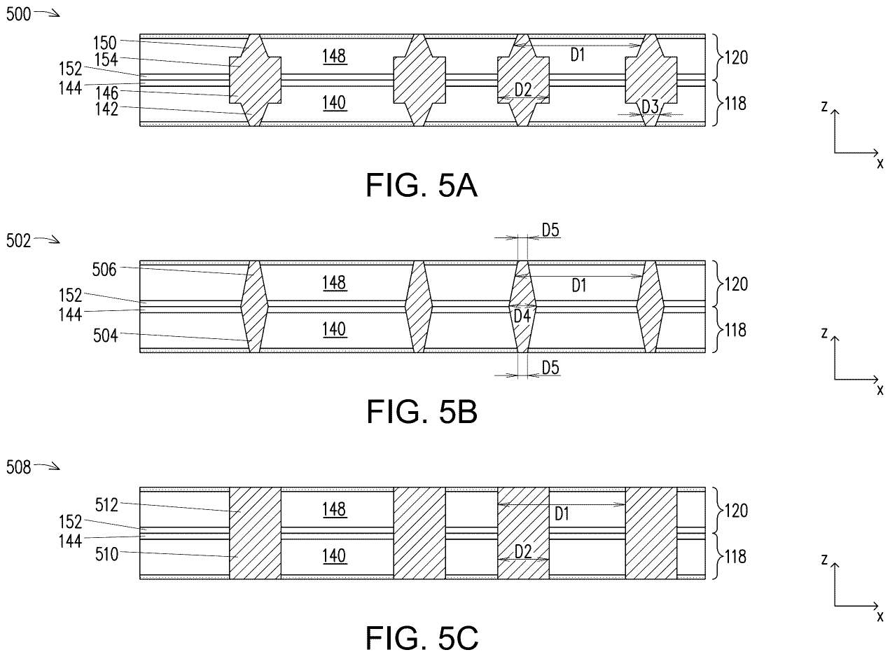

FIGS. 5A-5C are diagrams of example implementations of the semiconductor device 100 described herein. In some implementations, one or more of the semiconductor processing tools and/or a wafer/die transport tool may be used to perform one or more semiconductor processing operations to form the semiconductor device 100. In some implementations, one or more of the semiconductor processing operations described in connection with FIGS. 5A-5C may be performed using another semiconductor processing tool.

Turning to FIG. 5A, in the example implementation 500, the bonding structures include the bonding interconnect structures 150 and 142, and the bonding pads 146 and 154. Following the bonding operation, respective combinations of the bonding pads 146 and 154 form a continuous structure. The bonding interconnect structures 150 and 142 may have pitch (D1) in the x-direction that is less than or equal to approximately 2 micrometers. A width (D2) of the bonding pads 146 and 154 in the x-direction may be included in a range of approximately 0.3 micrometers to approximately 1 micrometer. A width (D3) of the bonding interconnect structures 150 and 142 in the x-direction may be included in a range of approximately 0.2 micrometers to approximately 0.5 micrometers. However, other values and ranges are within the scope of the present disclosure.

Turning to FIG. 5B, in the example implementation 502, the bonding structures include a combination of respective ones of a first plurality of bonding structures 504 with respective ones a second plurality of bonding structures 506. Following the bonding operation, the combination results in a plurality of continuous structures disposed through the bonding region 118 and the bonding region 120, where respective ones of the plurality of continuous structures have a tapered shape. A width in the x-direction of the respective ones of the plurality of continuous structures, each including a first bonding structure 504 and a second bonding structure 506, increases from an edge (e.g., top edge) of the bonding region 120 toward the bonding interface 110 (e.g., width D5 to width D4), and then decreases from the bonding interface 110 in the z-direction toward an edge (e.g., bottom edge) of the bonding region 118 (e.g., width D4 to width D5).

The bonding structures 504 extend through and/or are included in the carbide layer 136, extend through and/or are included in the dielectric layer 140, and extend through and/or are included in the bonding dielectric layer 144. The bonding structures 504 are electrically coupled and/or physically coupled with metallization structures 134a under the carbide layer 136. The bonding structures 506 extend through and/or are included in the carbide layer 138, extend through and/or are included in the dielectric layer 148, and extend through and/or are included in the bonding dielectric layer 152. The bonding structures 506 are electrically coupled and/or physically coupled with metallization structures 134a over the carbide layer 138. The bonding structures 504 and 506 may include one or more liner layers and a conductive fill layer. The one or more liner layers may include adhesion layers, barrier layers, and/or another type of liners. The bonding structures 504 and 506 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. Examples of materials for the one or more liner layers include tantalum nitride (TaN), titanium nitride (TiN), ruthenium (Ru), cobalt (Co), and/or ruthenium oxide (RuOx), among other examples.

The bonding structures 504 and 506 may have pitch (D1) in the x-direction that is less than or equal to approximately 2 micrometers. A width (D4) of the bonding structures 504 and 506 at the bonding interface in the x-direction may be included in a range of approximately 0.3 micrometers to approximately 1 micrometer. However, other values and ranges are within the scope of the present disclosure.

Turning to FIG. 5C, in the example implementation 508, the bonding structures include a combination of respective ones of a first plurality of bonding structures 510 with respective ones a second plurality of bonding structures 512. Following the bonding operation, the combination results in a plurality of continuous structures disposed through the bonding region 118 and the bonding region 120, where respective ones of the plurality of continuous structures have a substantially uniform width (D2) in the x-direction. The width (D2) in the x-direction of the respective ones of the plurality of continuous structures, each including a first bonding structure 510 and a second bonding structure 512, may be substantially uniform along a z-direction from an edge (e.g., top edge) of the bonding region 120 through the bonding interface 110 and to an edge (e.g., bottom edge) of the bonding region 118 (or vice versa).

The bonding structures 510 extend through and/or are included in the carbide layer 136, extend through and/or are included in the dielectric layer 140, and extend through and/or are included in the bonding dielectric layer 144. The bonding structures 504 are electrically coupled and/or physically coupled with metallization structures 134a under the carbide layer 136. The bonding structures 512 extend through and/or are included in the carbide layer 138, extend through and/or are included in the dielectric layer 148, and extend through and/or are included in the bonding dielectric layer 152. The bonding structures 512 are electrically coupled and/or physically coupled with metallization structures 134a over the carbide layer 138. The bonding structures 510 and 512 may include one or more liner layers and a conductive fill layer. The one or more liner layers may include adhesion layers, barrier layers, and/or another type of liners. The bonding structures 510 and 512 may include one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. Examples of materials for the one or more liner layers include tantalum nitride (TaN), titanium nitride (TiN), ruthenium (Ru), cobalt (Co), and/or ruthenium oxide (RuOx), among other examples.

The bonding structures 510 and 512 may have pitch (D1) in the x-direction that is less than or equal to approximately 2 micrometers. The width (D2) of the bonding structures 510 and 512 in the x-direction may be included in a range of approximately 0.3 micrometers to approximately 1 micrometer. However, other values and ranges are within the scope of the present disclosure.

As indicated above, FIGS. 5A-5C are provided as examples. Other examples may differ from what is described with regard to FIGS. 5A-5C.

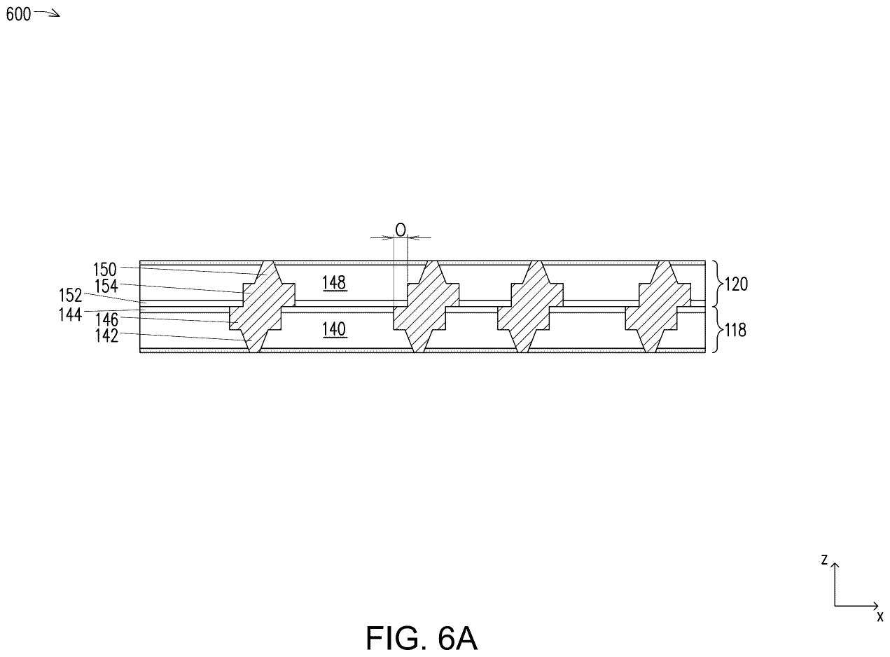

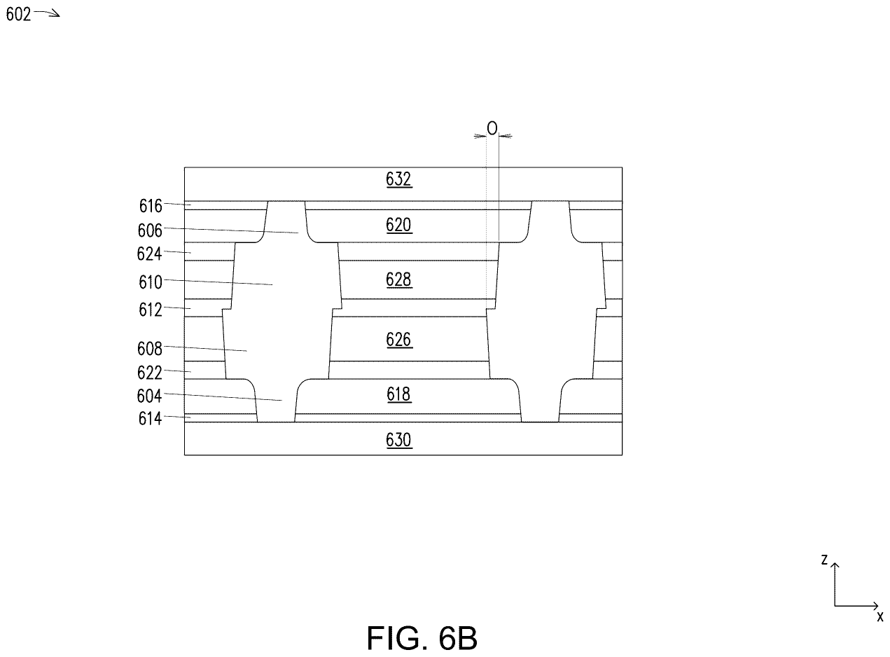

FIGS. 6A and 6B are diagrams of example implementations 600 and 602 of the semiconductor device 100 described herein. In some implementations, one or more of the semiconductor processing tools and/or a wafer/die transport tool may be used to perform one or more semiconductor processing operations to form the semiconductor device 100. In some implementations, one or more of the semiconductor processing operations described in connection with FIGS. 6A and 6B may be performed using another semiconductor processing tool.

Turning to FIG. 6A, in the example implementation 600, the bonding structures include the bonding interconnect structures 150 and 142, and the bonding pads 146 and 154. Following the bonding operation, respective combinations of the bonding pads 146 and 154 are in an offset arrangement, where bonding pads 146 and 154 that are bonded to (e.g., adjacent to) each other are offset or misaligned with respect to each other by a dimension (O). In some implementations, the offset dimension (O) may have an upper limit that is included in a range of approximately 60% to approximately 70% of a width in the x-direction of the bonding pads 146 and 154. For example, if a width of the bonding pads 146 and 154 in the x-direction is included in a range of approximately 0.3 micrometers to approximately 1 micrometer, then the upper limit of the offset may be included in a range of approximately 0.18 micrometers to approximately 0.7 micrometers. However, other values and ranges are within the scope of the present disclosure.

Turning to FIG. 6B, in the example implementation 600, the bonding structures include bonding interconnect structures 604 and 606, and bonding pads 608 and 610. Following the bonding operation, respective combinations of the bonding pads 608 and 610 are in an offset arrangement, where bonding pads 608 and 610 that are bonded to each other are offset or misaligned with respect to each other by the dimension (O) as discussed in connection with FIG. 6A. The bonding pads 608 and 610 are embedded in a bonding dielectric layer 612 at a bonding interface of the bonding pads 608 and 610. The bonding interconnect structures 604 and 606 are extend through and/or are included in respective carbide layers 614 and 616, and extend through and/or are included in respective dielectric layers 618 and 620. The dielectric layer 618 is included over and/or on the carbide layer 614, and the dielectric layer 620 is included under the carbide layer 616. The carbide layers 614 and 616 may be similar to the carbide layers 136 and 138.

The dielectric layers 618 and 620 may include a high density plasma (HDP) dielectric material and/or another suitable dielectric material. The bonding interconnect structures 604 and 606, and the bonding pads 608 and 610 each include one or more electrically conductive metals, such as copper (Cu), tungsten (W), cobalt (Co), ruthenium (Ru), titanium (Ti), aluminum (Al), gold (Au), and/or a combination thereof, among other examples of electrically conductive materials.

A nitride layer 622 may be included over and/or on the dielectric layer 618, and a nitride layer 624 may be included under the dielectric layer 620. A dielectric layer 626 is included over and/or on the nitride layer 622, and a dielectric layer 628 is included under the nitride layer 624. The bonding dielectric layer 612 is between the dielectric layers 626 and 628. The bonding pads 608 extend through and/or are included in the nitride layer 622, the dielectric layer 626, and the bonding dielectric layer 612. The bonding pads 610 extend through and/or are included in the nitride layer 624, the dielectric layer 628, and the bonding dielectric layer 612. The nitride layers 622 and 624 may be included in the bonding regions as ESLs. The nitride layers 622 and 624 may include a nitride-containing dielectric material such as a silicon nitride (SiₓN_{y} such as Si₃N₄) a silicon oxynitride (SiON), a silicon carbon nitride (SiCN), a silicon oxycarbonitride (SiOCN), and/or another nitride-containing dielectric material. The dielectric layers 626 and 628 may include an HDP dielectric material and/or another suitable dielectric material. The bonding dielectric layer 612 may include a silicon oxynitride (SiON) and/or another suitable bonding dielectric material. The carbide layer 614 is formed on an ILD layer 630 and the carbide layer 616 is formed under an ILD layer 632. The ILD layers 630 and 632 may be similar to the ILD layers 130.

As indicated above, FIGS. 6A and 6B are provided as examples. Other examples may differ from what is described with regard to FIGS. 6A and 6B.

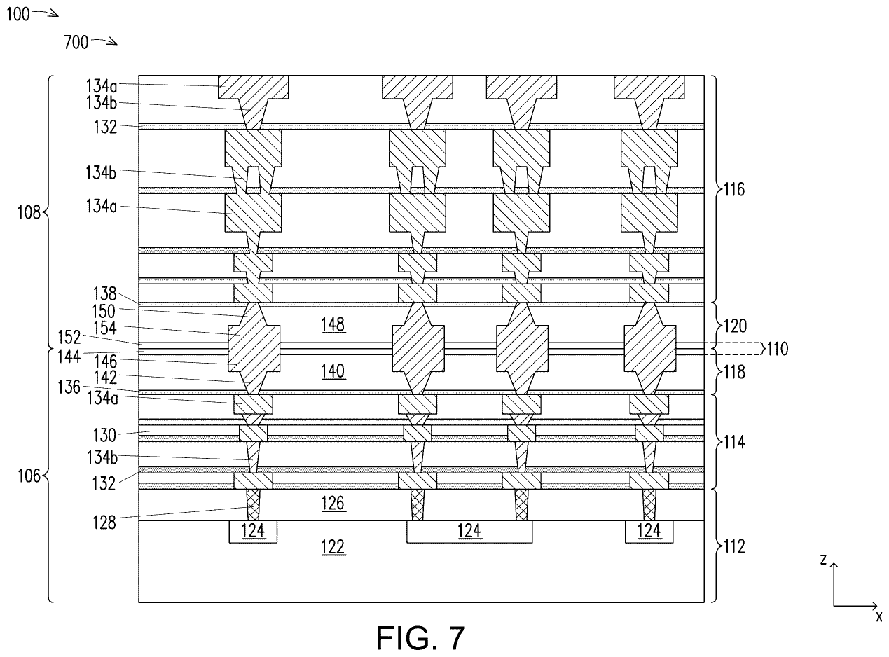

FIG. 7 is a diagram of an example implementation 700 of the semiconductor device 100 described herein. In the example implementation 700, the interconnect layer 114 includes one or more additional ILD layers 130 and ESLs 132 between the device layer 112 and the bonding region 118. One or more additional metallization layers (e.g., Mx) including metallization structures 134a are included in the one or more additional ILD layers 130 and ESLs 132. Interconnect structures 134b extend from the metallization structures 134a through the one or more additional ILD layers 130 and ESLs 132. As can be understood from FIGS. 1B and 7, there may be one or more metallization layers (e.g., Mx) between the device layer 112 and the bonding region 118. In more detail, the bonding regions 118 and 120 may be, for example, between M1 and M2 metallization layers, between M2 and M3 metallization layers, between M3 and M4 metallization layers, and so on.

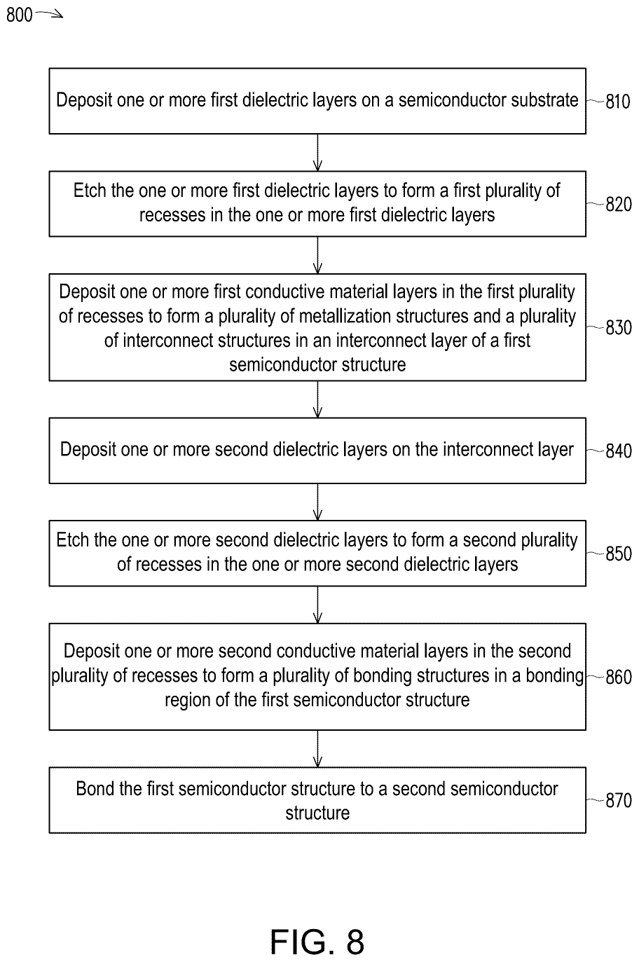

FIG. 8 is a flowchart of an example process 800 associated with forming a semiconductor device. In some implementations, one or more process blocks of FIG. 8 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 8, process 800 may include depositing one or more first dielectric layers (block 810). For example, one or more semiconductor processing tools may be used to deposit one or more first dielectric layers (e.g., ILD layers 130, ESLs 132) on a semiconductor substrate (e.g., substrate 202), as described herein.

As further shown in FIG. 8, process 800 may include etching the one or more first dielectric layers to form a first plurality of recesses in the one or more first dielectric layers (block 820). For example, one or more semiconductor processing tools may be used to etch the one or more first dielectric layers to form a first plurality of recesses (e.g., recesses 204) in the one or more first dielectric layers, as described herein.

As further shown in FIG. 8, process 800 may include depositing one or more first conductive material layers in the first plurality of recesses to form a plurality of metallization structures and a plurality of interconnect structures in an interconnect layer of a first semiconductor structure (block 830). For example, one or more semiconductor processing tools may be used to deposit one or more first conductive material layers in the first plurality of recesses to form a plurality of metallization structures (e.g., metallization structures 134a) and a plurality of interconnect structures (e.g., interconnect structures 134b) in an interconnect layer (e.g., interconnect layer 116) of a first semiconductor structure (e.g., second semiconductor die 108), as described herein.

As further shown in FIG. 8, process 800 may include depositing one or more second dielectric layers on the interconnect layer (block 840). For example, one or more semiconductor processing tools may be used to deposit one or more second dielectric layers (e.g., dielectric layer 148, bonding dielectric layer 152) on the interconnect layer, as described herein.

As further shown in FIG. 8, process 800 may include etching the one or more second dielectric layers to form a second plurality of recesses in the one or more second dielectric layers (block 850). For example, one or more semiconductor processing tools may be used to etch the one or more second dielectric layers to form a second plurality of recesses (e.g., recesses 208) in the one or more second dielectric layers, as described herein.

As further shown in FIG. 8, process 800 may include depositing one or more second conductive material layers in the second plurality of recesses to form a plurality of bonding structures in a bonding region of the first semiconductor structure (block 860). For example, one or more semiconductor processing tools may be used to deposit one or more second conductive material layers in the second plurality of recesses to form a plurality of bonding structures (e.g., bonding interconnect structures 150, bonding pads 154, bonding structures 506, bonding structures 512) in a bonding region (e.g., bonding region 120) of the first semiconductor structure, as described herein.

As further shown in FIG. 8, process 800 may include bonding the first semiconductor structure to a second semiconductor structure (block 870). For example, one or more semiconductor processing tools may be used to bond the first semiconductor structure to a second semiconductor structure (e.g., first semiconductor die 106), as described herein. In some implementations, the second semiconductor structure includes a device layer (e.g., device layer 112).

Process 800 may include additional implementations, such as any single implementation or any combination of implementations described below and/or in connection with one or more other processes described elsewhere herein.

In a first implementation, process 800 includes rotating, prior to depositing the one or more second dielectric layers on the interconnect layer, the first semiconductor structure to invert the first semiconductor structure relative to an orientation in which the one or more first conductive material layers were formed in the first plurality of recesses.

In a second implementation, alone or in combination with the first implementation, process 800 includes bonding an additional semiconductor substrate (e.g., substrate 206) to a top of the interconnect layer.

In a third implementation, alone or in combination with one or more of the first and second implementations, rotating the first semiconductor structure includes rotating the first semiconductor structure after bonding the additional semiconductor substrate to the top of the interconnect layer.

In a fourth implementation, alone or in combination with one or more of the first through third implementations, process 800 includes removing the semiconductor substrate prior to depositing the one or more second dielectric layers on the interconnect layer.

In a fifth implementation, alone or in combination with one or more of the first through fourth implementations, process 800 includes performing, prior to bonding the first semiconductor structure to the second semiconductor structure, and after forming the interconnect layer, an ultraviolet curing process on the first semiconductor structure.

In a sixth implementation, alone or in combination with one or more of the first through fifth implementations, process 800 includes performing, prior to bonding the first semiconductor structure to the second semiconductor structure, and after forming the bonding region, an ultraviolet curing process on the first semiconductor structure.

In a seventh implementation, alone or in combination with one or more of the first through sixth implementations, the plurality of bonding structures include a plurality of bonding interconnect structures, and where the plurality of bonding interconnect structures have an inverted orientation relative to an orientation of the plurality of interconnect structures in the interconnect layer.

Although FIG. 8 shows example blocks of process 800, in some implementations, process 800 includes additional blocks, fewer blocks, different blocks, or differently arranged blocks than those depicted in FIG. 8. Additionally, or alternatively, two or more of the blocks of process 800 may be performed in parallel.

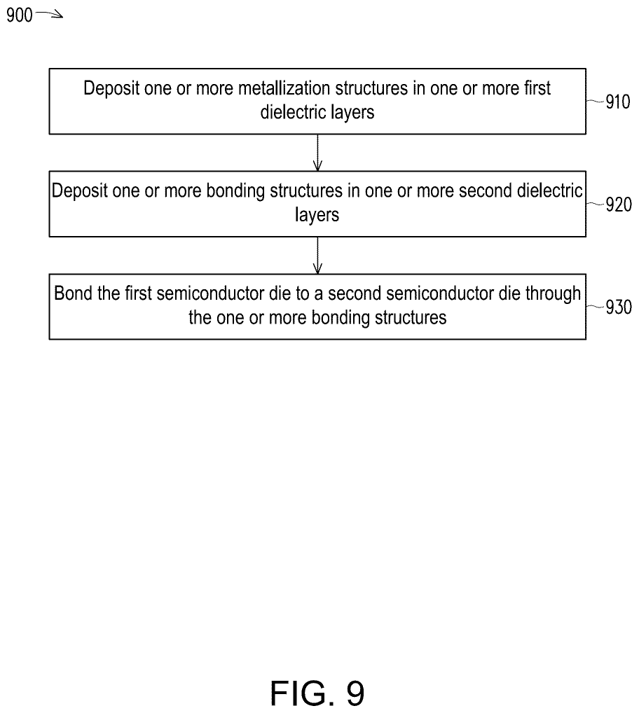

FIG. 9 is a flowchart of an example process 900 associated with forming a semiconductor device. In some implementations, one or more process blocks of FIG. 9 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 9, process 900 may include depositing one or more metallization structures in one or more first dielectric layers (block 910). For example, one or more semiconductor processing tools may be used to deposit one or more metallization structures (e.g., metallization structures 134a) in one or more first dielectric layers (e.g., ILD layers 130, ESLs 132), as described herein. In some implementations, the one or more first dielectric layers are over a semiconductor substrate (e.g., substrate 122) of a device layer (e.g., device layer 112) of a first semiconductor die (e.g., first semiconductor die 106). In some implementations, the one or more metallization structures are electrically connected to one or more devices (e.g., integrated circuit devices 124) in the device layer.

As further shown in FIG. 9, process 900 may include depositing one or more bonding structures in one or more second dielectric layers (block 920). For example, one or more semiconductor processing tools may be used to deposit one or more bonding structures (e.g., bonding interconnect structures 142, bonding pads 146, bonding structures 504, bonding structures 510) min one or more second dielectric layers (e.g., dielectric layer 140, bonding dielectric layer 144, carbide layer 136), as described herein. In some implementations, the one or more bonding structures are over the one or more metallization structures.

As further shown in FIG. 9, process 900 may include bonding the first semiconductor die to a second semiconductor die through the one or more bonding structures (block 930). For example, one or more semiconductor processing tools may be used to bond the first semiconductor die to a second semiconductor die (e.g., second semiconductor die 108) through the one or more bonding structures, as described herein. In some implementations, a charge reduction process may be performed on the second semiconductor die prior to the bonding of the first semiconductor die to the second semiconductor die.

Process 900 may include additional implementations, such as any single implementation or any combination of implementations described below and/or in connection with one or more other processes described elsewhere herein.

In a first implementation, the charge reduction process is performed with ultraviolet light.

In a second implementation, alone or in combination with the first implementation, the first semiconductor die is an active die and the second semiconductor die is a passive die.

In a third implementation, alone or in combination with one or more of the first and second implementations, the one or more metallization structures are electrically connected to the one or more devices through one or more first interconnect structures (e.g., interconnect structures 134b) oriented in an orientation direction with respect to an axis (e.g., x-axis) substantially parallel to a top surface of the semiconductor substrate, and the second semiconductor die includes one or more second interconnect structures (e.g., interconnect structures 134b) oriented in a same orientation direction with respect to the axis substantially parallel to the top surface of the semiconductor substrate as the orientation direction of the one or more first interconnect structures.

In a fourth implementation, alone or in combination with one or more of the first through third implementations, the one or more bonding structures include a first plurality of bonding structures (e.g., bonding pads 146, bonding interconnect structures 142) of the first semiconductor die, and second plurality of bonding structures (e.g., bonding pads 154, bonding interconnect structures 150) of the second semiconductor die, and where the second plurality of bonding structures are offset with respect to the first plurality of bonding structures.

In a fifth implementation, alone or in combination with one or more of the first through fourth implementations, process 900 includes removing a carrier substrate (e.g., substrate 206) from a top of the second semiconductor die after the bonding of the first semiconductor die to the second semiconductor die, where the removing exposes a top surface of an interconnect layer (e.g., interconnect layer 116) of the second semiconductor die.

Although FIG. 9 shows example blocks of process 900, in some implementations, process 900 includes additional blocks, fewer blocks, different blocks, or differently arranged blocks than those depicted in FIG. 9. Additionally, or alternatively, two or more of the blocks of process 900 may be performed in parallel.

In this way, a device layer and an interconnect layer of a semiconductor device are formed as separate semiconductor structures (e.g., on different semiconductor substrates) and then, following formation of the device and interconnect layers, the separate semiconductor structures are bonded together. In some implementations, a charge reduction process (e.g., an ultraviolet (UV) light curing process) is performed on a first semiconductor structure including the interconnect layer so that charges resulting from plasma processing to form the interconnect layer can be removed prior to bonding the first semiconductor structure including the interconnect layer to a second semiconductor structure including the device layer. As a result of the charge removal, current flow in dielectric layers (e.g., gate oxide layers) in a device layer, and the resulting plasma-induced damage to the dielectric layers, can be reduced and/or prevented in comparison to when the device layer and the interconnect layer are sequentially formed on the same semiconductor substrate.

Additionally, by fabricating the device layer and the interconnect layer as different semiconductor structures to be bonded together, the device layer and the interconnect layer can be manufactured concurrently, thereby reducing the overall time for manufacturing the semiconductor device in comparison to when the device layer and the interconnect layer are sequentially formed on the same semiconductor substrate. For example, manufacturing the device layer and the interconnect layer on separate semiconductor substrates may enable processes that are used to form the device layer and the interconnect layer to be customized for the device layer and the interconnect layer, thereby increasing manufacturing efficiency and improving resulting device performance. In more detail, manufacturing techniques that may be beneficial for the interconnect layer, but detrimental to the device layer (e.g., plasma operations), may be used to manufacture the interconnect layer on a separate semiconductor substrate, with little or no impact on the device layer. Similarly, manufacturing techniques that may be beneficial for the device layer, but detrimental to the interconnect layer, may be used to manufacture the device layer on a separate semiconductor substrate, with little or no impact to the interconnect layer.

As described in greater detail above, some implementations described herein provide a method. The method includes depositing one or more first dielectric layers on a semiconductor substrate. The method includes etching the one or more first dielectric layers to form a first plurality of recesses in the one or more first dielectric layers. The method includes depositing one or more first conductive material layers in the first plurality of recesses to form a plurality of metallization structures and a plurality of interconnect structures in an interconnect layer of a first semiconductor structure. The method includes depositing one or more second dielectric layers on the interconnect layer. The method includes etching the one or more second dielectric layers to form a second plurality of recesses in the one or more second dielectric layers. The method includes depositing one or more second conductive material layers in the second plurality of recesses to form a plurality of bonding structures in a bonding region of the first semiconductor structure. The method includes bonding the first semiconductor structure to a second semiconductor structure, where the second semiconductor structure includes a device layer.

As described in greater detail above, some implementations described herein provide a method. The method includes depositing one or more metallization structures in one or more first dielectric layers, where the one or more first dielectric layers are over a semiconductor substrate of a device layer of a first semiconductor die, and where the one or more metallization structures are electrically connected to one or more devices in the device layer. The method includes depositing one or more bonding structures in one or more second dielectric layers, where the one or more bonding structures are over the one or more metallization structures. The method includes bonding the first semiconductor die to a second semiconductor die through the one or more bonding structures, where a charge reduction process is performed on the second semiconductor die prior to the bonding of the first semiconductor die to the second semiconductor die.

As described in greater detail above, some implementations described herein provide a semiconductor device. The semiconductor device includes a first semiconductor structure bonded to a second semiconductor structure such that the first semiconductor structure and the second semiconductor structure are stacked in the semiconductor device. The first semiconductor structure includes a device layer including one or more devices, a first interconnect layer on the device layer, where the first interconnect layer includes a first plurality of interconnect structures, and a first bonding region on the first interconnect layer, where the first bonding region includes a first plurality of bonding structures and at least one bonding dielectric layer. The second semiconductor structure includes a second bonding region opposite the first bonding region, where the second bonding region includes a second plurality of bonding structures and at least one other bonding dielectric layer, and a second interconnect layer on the second bonding region, where the second interconnect layer includes a second plurality of interconnect structures, and an orientation of the second plurality of interconnect structures is the same as an orientation of the first plurality of interconnect structures.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
depositing one or more first dielectric layers on a semiconductor substrate;
etching the one or more first dielectric layers to form a first plurality of recesses in the one or more first dielectric layers;
depositing one or more first conductive material layers in the first plurality of recesses to form a plurality of metallization structures and a plurality of interconnect structures in an interconnect layer of a first semiconductor structure;
depositing one or more second dielectric layers on the interconnect layer;
etching the one or more second dielectric layers to form a second plurality of recesses in the one or more second dielectric layers;
depositing one or more second conductive material layers in the second plurality of recesses to form a plurality of bonding structures in a bonding region of the first semiconductor structure; and
bonding the first semiconductor structure to a second semiconductor structure,
wherein the second semiconductor structure comprises a device layer.

2. The method of claim 1, further comprising rotating, prior to depositing the one or more second dielectric layers on the interconnect layer, the first semiconductor structure to invert the first semiconductor structure relative to an orientation in which the one or more first conductive material layers were formed in the first plurality of recesses.

3. The method of claim 2, further comprising bonding an additional semiconductor substrate to a top of the interconnect layer.

4. The method of claim 3, wherein rotating the first semiconductor structure comprises:
rotating the first semiconductor structure after bonding the additional semiconductor substrate to the top of the interconnect layer.

5. The method of claim 2, further comprising removing the semiconductor substrate prior to depositing the one or more second dielectric layers on the interconnect layer.

6. The method of claim 1, further comprising performing, prior to bonding the first semiconductor structure to the second semiconductor structure, and after forming the interconnect layer, an ultraviolet curing process on the first semiconductor structure.

7. The method of claim 1, further comprising performing, prior to bonding the first semiconductor structure to the second semiconductor structure, and after forming the bonding region, an ultraviolet curing process on the first semiconductor structure.

8. The method of claim 1, wherein the plurality of bonding structures comprise a plurality of bonding interconnect structures, and
wherein the plurality of bonding interconnect structures have an inverted orientation relative to an orientation of the plurality of interconnect structures in the interconnect layer.

9. A method, comprising:
depositing one or more metallization structures in one or more first dielectric layers,
wherein the one or more first dielectric layers are over a semiconductor substrate of a device layer of a first semiconductor die, and
wherein the one or more metallization structures are electrically connected to one or more devices in the device layer;
depositing one or more bonding structures in one or more second dielectric layers,
wherein the one or more bonding structures are over the one or more metallization structures; and
bonding the first semiconductor die to a second semiconductor die through the one or more bonding structures,
wherein a charge reduction process is performed on the second semiconductor die prior to the bonding of the first semiconductor die to the second semiconductor die.

10. The method of claim 9, wherein the charge reduction process is performed with ultraviolet light.

11. The method of claim 9, wherein the first semiconductor die is an active die and the second semiconductor die is a passive die.

12. The method of claim 9, wherein the one or more metallization structures are electrically connected to the one or more devices through one or more first interconnect structures oriented in an orientation direction with respect to an axis substantially parallel to a top surface of the semiconductor substrate, and
wherein the second semiconductor die comprises one or more second interconnect structures oriented in a same orientation direction with respect to the axis substantially parallel to the top surface of the semiconductor substrate as the orientation direction of the one or more first interconnect structures.

13. The method of claim 9, wherein the one or more bonding structures comprise a first plurality of bonding structures of the first semiconductor die, and second plurality of bonding structures of the second semiconductor die, and
wherein the second plurality of bonding structures are offset with respect to the first plurality of bonding structures.

14. The method of claim 9, further comprising removing a carrier substrate from a top of the second semiconductor die after the bonding of the first semiconductor die to the second semiconductor die,
wherein the removing exposes a top surface of an interconnect layer of the second semiconductor die.

15. A semiconductor device, comprising:
a first semiconductor structure bonded to a second semiconductor structure such that the first semiconductor structure and the second semiconductor structure are stacked in the semiconductor device,
wherein the first semiconductor structure comprises:
a device layer comprising one or more devices;
a first interconnect layer on the device layer,
wherein the first interconnect layer comprises a first plurality of interconnect structures; and
a first bonding region on the first interconnect layer,
wherein the first bonding region comprises a first plurality of bonding structures and at least one bonding dielectric layer; and
wherein the second semiconductor structure comprises:
a second bonding region opposite the first bonding region,
wherein the second bonding region comprises a second plurality of bonding structures and at least one other bonding dielectric layer; and
a second interconnect layer on the second bonding region,
wherein the second interconnect layer comprises a second plurality of interconnect structures, and
wherein an orientation of the second plurality of interconnect structures is the same as an orientation of the first plurality of interconnect structures.

16. The semiconductor device of claim 15, wherein the second plurality of bonding structures comprise a plurality of bonding interconnect structures, and
wherein the orientation of the second plurality of interconnect structures is different from an orientation of the plurality of bonding interconnect structures.

17. The semiconductor device of claim 15, wherein the first plurality of bonding structures comprise a plurality of bonding interconnect structures, and
wherein the orientation of the second plurality of interconnect structures is the same as an orientation of the plurality of bonding interconnect structures.

18. The semiconductor device of claim 15, wherein the first plurality of bonding structures and the second plurality of bonding structures comprise a plurality of continuous structures disposed through the first bonding region and the second bonding region, and
wherein respective ones of the plurality of continuous structures have a substantially uniform width from an edge of the first bonding region and to an edge of the second bonding region.

19. The semiconductor device of claim 15, wherein the first plurality of bonding structures and the second plurality of bonding structures comprise a plurality of continuous structures disposed through the first bonding region and the second bonding region,
wherein respective ones of the plurality of continuous structures have a tapered shape, and
wherein a width of the respective ones of the plurality of continuous structures increases from an edge of the first bonding region in a direction toward a bonding interface and from an edge of the second bonding region toward the bonding interface.

20. The semiconductor device of claim 15, wherein the first plurality of bonding structures comprises a first plurality of bonding pads in a first bonding dielectric layer,
wherein the second plurality of bonding structures comprises a second plurality of bonding pads in a second bonding dielectric layer, and
wherein respective bonding pads of the first plurality of bonding pads are misaligned with adjacent bonding pads of the second plurality of bonding pads.
